(19) United States
(12) Patent Application Publication
(10) Pub. No.: US 2024/0105867 A1
(43) Pub. Date: Mar. 28, 2024

(54) LIGHT-RECEIVING DEVICE AND COMMUNICATION DEVICE

(71) Applicant: NEC Corporation, Minato-Tokyo (JP)

(72) Inventors: Koya TAKATA, Tokyo (JP); Hisashi MIZUMOTO, Tokyo (JP); Fujio OKUMURA, Kanagawa (JP)

(73) Assignee: NEC Corporation, Minato-Tokyo (JP)

(21) Appl. No.: 18/270,267

(22) PCT Filed: Oct. 25, 2021
(86) PCT No.: PCT/JP2021/039348

§ 371 Date: Jun. 29, 2023

(30) Foreign Application Priority Data
Jan. 5, 2021 (JP) 2021-000310
Jun. 28, 2021 (JP) 2021-106392

(51) Int. Cl. H01L 31/0232; H04B 10/112; H04B 10/67

(52) U.S. Cl. CPC H01L 31/0232; H04B 10/112; H04B 10/67

(57) ABSTRACT

A light-receiving device that includes a condenser lens that condenses a spatial optical signal, a beam control element that emits an optical signal derived from the spatial optical signal condensed by the condenser lens toward a predetermined region, and a light-receiving element that is disposed with a light-receiving portion facing the predetermined region and receives the optical signal.

### TECHNICAL FIELD

The present disclosure relates to a light-receiving device or the like that receives a spatial optical signal.

### BACKGROUND ART

In optical spatial communication, optical signals (hereinafter, also referred to as a spatial optical signal) propagating in space are transmitted and received without using a medium such as an optical fiber. In order to receive a spatial optical signal that spreads and propagates in a space, a condenser lens as large as possible is required. In optical spatial communication, a photodiode having a small capacitance is required to perform high speed communication. Since such a photodiode has a very small light-receiving surface, it is difficult to condense spatial optical signals coming from various directions toward the light-receiving surface with a large condenser lens.

PTL 1 discloses a light-receiving device that filters condensed light. The device of PTL 1 includes a first condenser lens, a collimator lens, a band pass filter, and a light-receiving element. The collimator lens has a focal distance shorter than the focal distance of the first condenser lens, and converts light condensed by the condenser lens into parallel light. The parallel light from the collimator lens is incident perpendicularly to the filter surface of the band pass filter. The light transmitted through the band pass filter that transmits only the wavelength of the incident light is received by the light-receiving element. PTL 1 discloses a configuration in which a second condenser lens that condenses light having passed through a band pass filter is disposed or an aperture is disposed at a focal position of the condenser lens, so that light condensed by the condenser lens is easily guided to a light-receiving element. PTL 1 discloses a mechanism that moves a condenser lens and an aperture in three axial directions in accordance with an incident angle of light to adjust the condenser lens and the aperture to an optimum position.

### CITATION LIST

### Patent Literature

PTL 1: JP 2019-186595 A

### SUMMARY OF INVENTION

### Technical Problem

According to the method of PTL 1, the spatial light can be guided to the light-receiving element by condensing the light passing through the band pass filter on the second condenser lens or adjusting the condenser lens and the aperture to an optimum position in accordance with the incident angle of the light. However, in the method of PTL 1, the intensity of the light guided to the light-receiving element changes according to the incident angle of the spatial light. Therefore, in the method of PTL 1, the spatial light cannot be efficiently received depending on the incoming direction of the spatial light.

An object of the present disclosure is to provide a light-receiving device and the like capable of efficiently receiving a spatial optical signal coming from any direction.

### Solution to Problem

A light-receiving device according to an aspect of the present disclosure includes a condenser lens that condenses a spatial optical signal, a beam control element that emits an optical signal derived from the spatial optical signal condensed by the condenser lens toward a predetermined region, and a light-receiving element that is disposed with a light-receiving portion facing the predetermined region and receives the optical signal.

### Advantageous Effects of Invention

According to the present disclosure, it is possible to provide a light-receiving device and the like capable of efficiently receiving a spatial optical signal coming from any direction.

### BRIEF DESCRIPTION OF DRAWINGS

FIG. 1 is a conceptual diagram illustrating an example of a configuration of a light-receiving device of a first example embodiment.

FIG. 2 is a conceptual diagram illustrating an example of a trajectory of light in the light-receiving device of the first example embodiment.

FIG. 3 is a conceptual diagram illustrating an example of a trajectory of light in the light-receiving device of the first example embodiment.

FIG. 4 is a conceptual diagram illustrating an example of a beam control element included in the light-receiving device of the first example embodiment.

FIG. 5 is a conceptual diagram illustrating an example of a configuration of a light-receiving device of a second example embodiment.

FIG. 6 is a conceptual diagram illustrating an example of a trajectory of light in a light-receiving device of the second example embodiment.

FIG. 7 is a conceptual diagram illustrating a first example of a light pipe included in the light-receiving device of the second example embodiment.

FIG. 8 is a conceptual diagram illustrating a second example of a light pipe included in the light-receiving device of the second example embodiment.

FIG. 9 is a conceptual diagram illustrating a third example of a light pipe included in the light-receiving device of the second example embodiment.

FIG. 10 is a conceptual diagram illustrating a fourth example of the light pipe included in the light-receiving device of the second example embodiment.

FIG. 11 is a conceptual diagram illustrating a fifth example of the light pipe included in the light-receiving device of the second example embodiment.

FIG. 12 is a conceptual diagram illustrating an example of a configuration of a light-receiving device of a third example embodiment.

FIG. 13 is a conceptual diagram illustrating an example of a trajectory of light in the light-receiving device of the third example embodiment.

FIG. 14 is a conceptual diagram illustrating an example of a configuration of a light-receiving device of a fourth example embodiment.

FIG. 15 is a conceptual diagram illustrating an example of a trajectory of light in the light-receiving device of the fourth example embodiment.

FIG. 16 is a conceptual diagram illustrating an example of a trajectory of light in a modification example of the light-receiving device of the fourth example embodiment.

FIG. 17 is a conceptual diagram illustrating an example of a configuration of a light-receiving device of a fifth example embodiment.

FIG. 18 is a conceptual diagram illustrating an example of a trajectory of light in the light-receiving device of the fifth example embodiment.

FIG. 19 is a conceptual diagram for explaining an example of a fiber bundle included in a light-receiving device of a modification example of the fifth example embodiment.

FIG. 20 is a conceptual diagram illustrating an example of a configuration of the light-receiving device of a modification example of the fifth example embodiment.

FIG. 21 is a conceptual diagram illustrating an example of a configuration of a light-receiving device of a sixth example embodiment.

FIG. 22 is a conceptual diagram illustrating an example of a trajectory of light in the light-receiving device of the sixth example embodiment.

FIG. 23 is a block diagram illustrating an example of a configuration of a decoder included in the light-receiving device of the sixth example embodiment.

FIG. 24 is a conceptual diagram illustrating an example of a configuration of a light-receiving device of a seventh example embodiment.

FIG. 25 is a conceptual diagram illustrating an example of a trajectory of light in the light-receiving device of the seventh example embodiment.

FIG. 26 is a block diagram illustrating an example of a configuration of a decoder included in the light-receiving device of the seventh example embodiment.

FIG. 27 is a conceptual diagram illustrating an example of a configuration of a communication device of an eighth example embodiment.

FIG. 28 is a conceptual diagram illustrating an example of a configuration of a light transmitting unit included in the communication device of the eighth example embodiment.

FIG. 29 is a conceptual diagram illustrating an application example of the communication device of the eighth example embodiment.

FIG. 30 is a conceptual diagram illustrating an example of a configuration of a light-receiving device of a ninth example embodiment.

FIG. 31 is a block diagram illustrating an example of a hardware configuration that executes control and processing of each example embodiment.

### EXAMPLE EMBODIMENT

Hereinafter, example embodiments of the present invention will be described with reference to the drawings. However, the example embodiments described below have technically preferable limitations for carrying out the present invention, but the scope of the invention is not limited to the following. In all the drawings used in the following description of the example embodiment, the same reference numerals are given to the same parts unless there is a particular reason. In the following example embodiments, repeated description of similar configurations and operations may be omitted. The directions of the arrows in the drawings illustrate examples, and do not limit the directions of light and signals.

A line indicating a trajectory of light in the drawings is conceptual, and does not accurately indicate an actual traveling direction or state of light. For example, in the following drawings, a change in a traveling direction or a state of light due to refraction, reflection, diffusion, or the like at an interface between air and a substance may be omitted, or a light flux may be expressed by one line.

### First Example Embodiment

First, a light-receiving device according to the first example embodiment will be described with reference to the drawings. The light-receiving device of the present example embodiment is used for optical spatial communication in which optical signals (hereinafter, also referred to as spatial optical signals) propagating in a space are transmitted and received without using a medium such as an optical fiber. The light-receiving device of the present example embodiment may be used for applications other than optical spatial communication as long as the light-receiving device receives light propagating in a space. Hereinafter, the spatial optical signal is regarded as parallel light because it comes from a sufficiently distant position.

(Configuration)

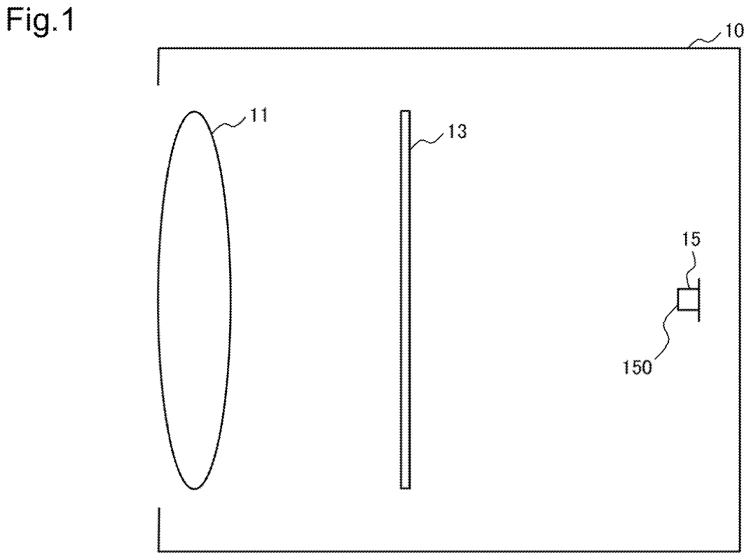

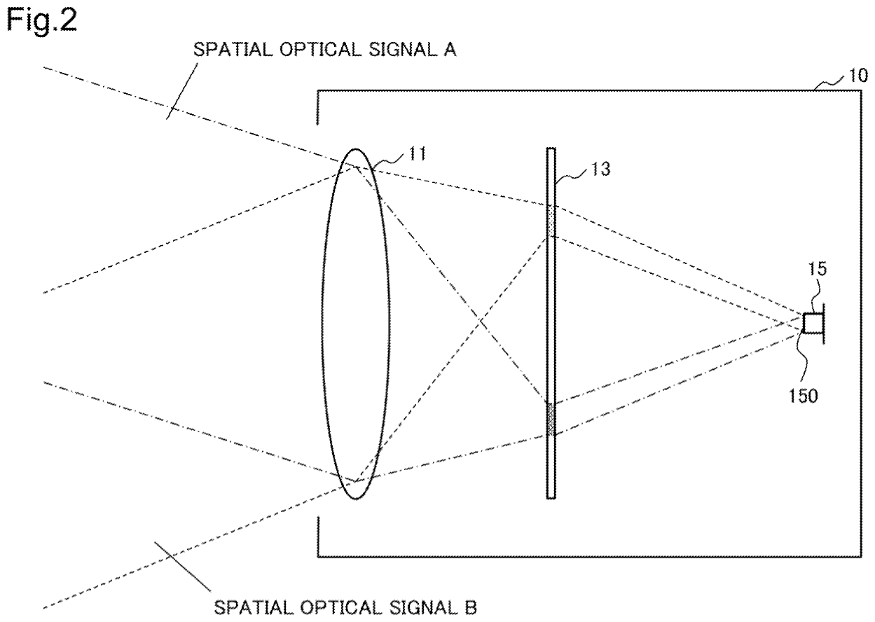

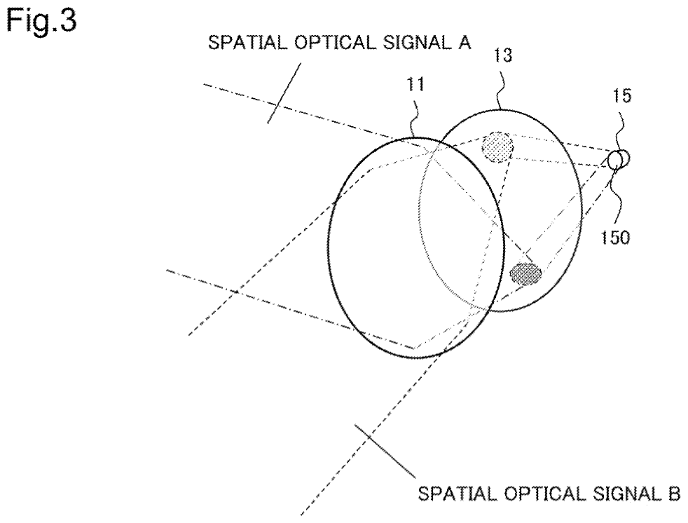

FIG. 1 is a conceptual diagram illustrating an example of a configuration of a light-receiving device 10 of the present example embodiment. The light-receiving device 10 includes a condenser lens 11, a beam control element 13, and a light-receiving element 15. FIGS. 2 and 3 are conceptual diagrams for describing an example of a trajectory of light received by the light-receiving device 10. FIGS. 1 and 2 are diagrams of the internal configuration of the light-receiving device 10 when viewed from the lateral direction. FIG. 3 is a perspective view of the internal configuration of the light-receiving device 10 when viewed obliquely from the front.

The condenser lens 11 is an optical element that condenses a spatial optical signal coming from the outside. The light derived from the spatial optical signal condensed by the condenser lens 11 is condensed toward the incident face of the beam control element 13. The light derived from the spatial optical signal condensed by the condenser lens 11 is referred to as an optical signal. For example, the condenser lens 11 can be made of a material such as glass or plastic. For example, the condenser lens 11 is made of a material such as quartz. When the spatial optical signal is light in an infrared region (hereinafter, also referred to as infrared rays), a material that transmits infrared rays is preferably used for the condenser lens 11. For example, the condenser lens 11 may be made of silicon, germanium, or a chalcogenide material. The material of the condenser lens 11 is not limited as long as it can refract and transmit the light in the wavelength region of the spatial optical signal.

The beam control element 13 is disposed behind the condenser lens 11. The beam control element 13 is disposed in such a way that the incident face faces an emission face of the condenser lens 11. In order for the light-receiving element 15 to efficiently receive the optical signal, it is preferable to dispose the beam control element 13 in such a way that the incident face of the beam control element 13 is positioned ahead the focal position of the condenser lens 11. The optical signal incident on the incident face of the beam control element 13 is emitted from the emission face toward a predetermined region. That is, an emission direction of the optical signal incident on the beam control element 13 is controlled, and the optical signal is emitted toward a light-receiving portion 150 of the light-receiving element 15 disposed at the predetermined region.

In the example of FIG. 3, a spatial optical signal A and a spatial optical signal B coming from different directions are incident on the condenser lens 11. The optical signals derived from the spatial optical signal A and the spatial optical signal B are condensed by the condenser lens 11, and are incident on different regions (also referred to as beam control regions) of the beam control element 13. The beam control element 13 emits optical signals incident on any beam control region toward the same predetermined region. As a result, the optical signals derived from the spatial optical signal A and the spatial optical signal B are received by the light-receiving element 15 disposed with the light-receiving portion 150 facing the predetermined region.

For example, the beam control element 13 is achieved by a near-field diffractive optical element, a hologram element, a reflection type diffractive optical element, or the like. The beam control element 13 is not limited to the above example as long as it can emit the optical signal incident on the incident face toward the predetermined region where the light-receiving portion 150 of the light-receiving element 15 is located.

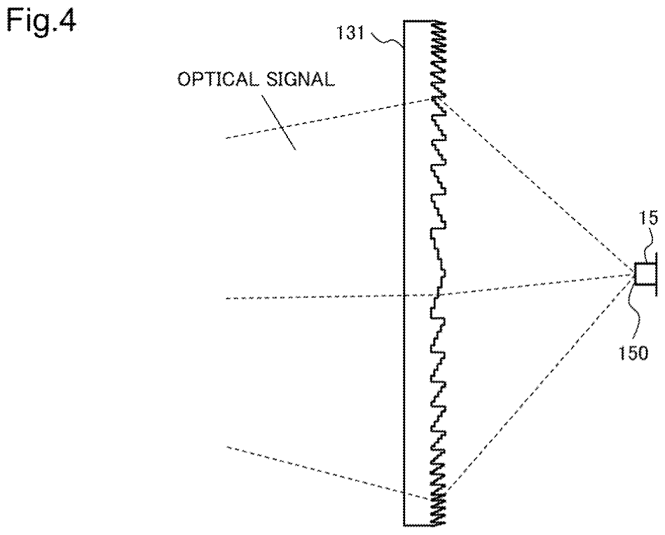

FIG. 4 is a cross-sectional view illustrating an example (near-field diffractive optical element 131) of the near-field diffractive optical element that achieves the beam control element 13. On the emission face of the near-field diffractive optical element 131, sub-micron order irregularities are formed. The near-field diffractive optical element 131 of FIG. 4 conceptually depicts an element that achieves the beam control element 13, and is not drawn to the actual scale of the unevenness. The near-field diffractive optical element 131 guides the optical signal condensed by the condenser lens 11 to a predetermined region where the light-receiving portion 150 of the light-receiving element 15 is disposed.

The light-receiving element 15 is disposed behind the beam control element 13. The light-receiving element 15 includes the light-receiving portion 150 that receives the optical signal emitted from the beam control element 13. The light-receiving element 15 is disposed in such a way that light-receiving portion 150 faces the emission face of the beam control element 13. The light-receiving element 15 is disposed in such a way that the light-receiving portion 150 is located at a predetermined region. The optical signal emitted from the beam control element 13 is received by the light-receiving portion 150 of the light-receiving element 15 located at a predetermined region.

The light-receiving element 15 receives light in a wavelength region of an optical signal to be received. For example, the light-receiving element 15 receives an optical signal in an infrared region. The light-receiving element 15 receives an optical signal having a wavelength in a 1.5 μm (micrometer) band, for example. The wavelength band of the optical signal received by the light-receiving element 15 is not limited to the 1.5 μm band. The wavelength band of the optical signal received by the light-receiving element 15 can be set in accordance with the wavelength of the spatial optical signal transmitted from the light transmitting device (not illustrated). The wavelength band of the optical signal received by the light-receiving element 15 may be set to, for example, a 0.8 μm band, a 1.55 μm band, or a 2.2 μm band. The wavelength band of the optical signal received by the light-receiving element 15 may be, for example, a 0.8 to 1 μm band. When the wavelength band of the optical signal is short, absorption by moisture in the atmosphere is small, which is advantageous for optical spatial communication during rainfall. The light-receiving element 15 may receive an optical signal in the visible region. When the light-receiving element 15 is saturated with intense sunlight, the light-receiving element cannot read the optical signal derived from the spatial optical signal. Therefore, a color filter that selectively passes the light in the wavelength band of the spatial optical signal may be installed in the preceding stage of the light-receiving element 15.

The light-receiving element 15 converts the received optical signal into an electric signal. The light-receiving element 15 outputs the converted electric signal to a decoder (not illustrated). For example, the light-receiving element 15 can be achieved by an element such as a photodiode or a phototransistor. For example, the light-receiving element 15 is achieved by an avalanche photodiode. The light-receiving element 15 achieved by the avalanche photodiode can support high speed communication. The light-receiving element 15 may be achieved by an element other than a photodiode, a phototransistor, or an avalanche photodiode as long as an optical signal can be converted into an electric signal.

In order to improve the communication speed, the light-receiving portion 150 of the light-receiving element 15 is preferably as small as possible. For example, the light-receiving portion 150 of the light-receiving element 15 has a light-receiving surface having a diameter of about 0.1 to 0.3 mm (millimeter). The optical signal condensed by the condenser lens 11 is condensed within a certain range depending on the incoming direction of the spatial optical signal, but cannot be condensed in a predetermined region where the light-receiving portion 150 of the light-receiving element 15 is disposed. In the present example embodiment, by using the beam control element 13 that selectively guides the optical signal condensed by the condenser lens 11 to a predetermined region, the optical signal condensed by the condenser lens 11 is guided to the predetermined region where the light-receiving portion 150 of the light-receiving element 15 is located. Therefore, the light-receiving device 10 can efficiently guide the spatial optical signal arriving at the incident face of the condenser lens 11 from any direction to the light-receiving portion 150 of the light-receiving element 15.

As described above, the light-receiving device of the present example embodiment includes the condenser lens, the beam control element, and the light-receiving element. The condenser lens receives a spatial optical signal. The beam control element emits an optical signal derived from the spatial optical signal condensed by the condenser lens toward a predetermined region. For example, the beam control measure is a near-field diffractive optical element that diffracts the optical signal condensed by the condenser lens toward a predetermined region. The light-receiving element is disposed with the light-receiving portion facing a predetermined region. The light-receiving element receives an optical signal.

According to the light-receiving device of the present example embodiment, by guiding the optical signal condensed by the condenser lens to the predetermined region by the beam control element, spatial light coming from any direction can be efficiently received.

### Second Example Embodiment

Next, a light-receiving device of the second example embodiment will be described with reference to the drawings. The light-receiving device of the present example embodiment includes a light pipe that guides an optical signal emitted from a beam control element to a light-receiving portion of the light-receiving element. The light pipe is a member that guides the optical signal emitted from the beam control element to the light-receiving portion of the light-receiving element.

(Configuration)

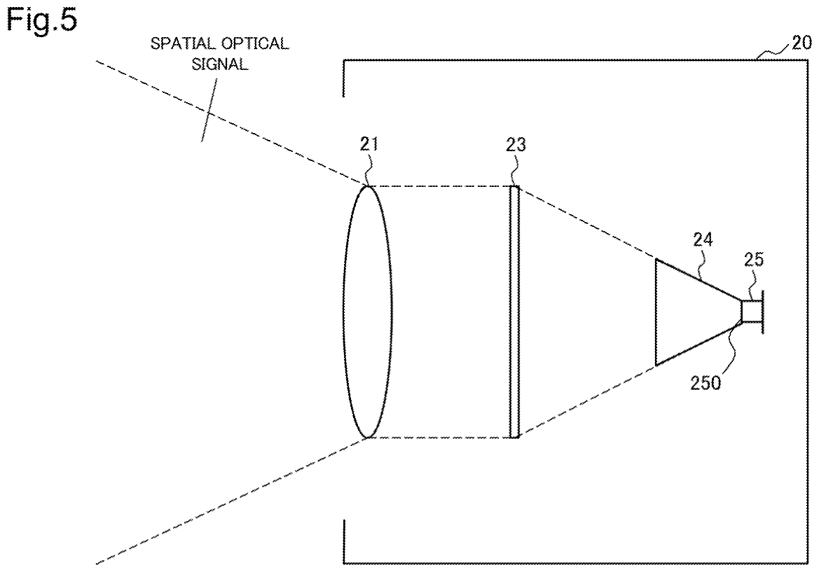

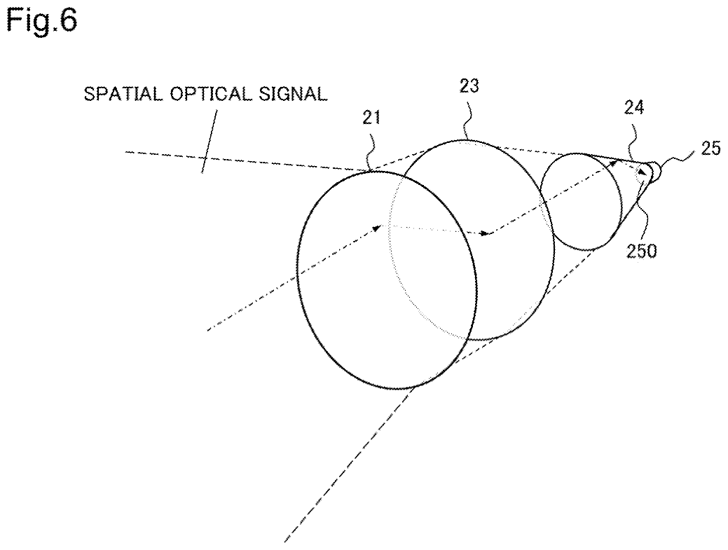

FIG. 5 is a conceptual diagram illustrating an example of a configuration of a light-receiving device 20 of the present example embodiment. The light-receiving device 20 includes a condenser lens 21, a beam control element 23, a light pipe 24, and a light-receiving element 25. FIG. 5 is a view of the internal configuration of the light-receiving device 20 when viewed from the lateral direction. FIG. 6 is a conceptual diagram for describing an example of a trajectory of light received by the light-receiving device 20. FIG. 6 is a perspective view of the internal configuration of the light-receiving device 20 when viewed obliquely from the front.

The condenser lens 21 is an optical element that condenses a spatial optical signal coming from the outside. The optical signal condensed by the condenser lens 21 is condensed toward the incident face of the beam control element 23. The condenser lens 21 has the same configuration as the condenser lens 11 of the first example embodiment.

Light beam control element 23 is disposed behind the condenser lens 21. The beam control element 23 is disposed in such a way that the incident face faces an emission face of the condenser lens 21. The optical signal incident on the incident face of the beam control element 23 is emitted toward a predetermined region with a close distance. An emission direction of the optical signal incident on the incident face of the beam control element 23 is controlled, and the optical signal is emitted toward the incident face of the light pipe 24. The beam control element 23 has the same configuration as the beam control element 13 of the first example embodiment.

The light pipe 24 is provided in association with the light-receiving element 25. The light pipe 24 has an incident face on which the spatial optical signal is incident and an emission face from which the optical signal guided inside the light pipe 24 is emitted. The emission face has a smaller area than the incident face. The light pipe 24 is disposed in such a way that its incident face is located at a predetermined region. The emission face of the light pipe 24 is disposed in such a way as to be in contact with a light-receiving portion 250 of the light-receiving element 25 with which the light pipe 24 is associated. The emission face of the light pipe 24 and the light-receiving portion 250 of the light-receiving element 25 may not be in contact with each other as long as the optical signal emitted from the emission face of the light pipe 24 is incident on the light-receiving portion 250 of the light-receiving element 25. Although FIG. 5 illustrates an example in which the incident face and the emission face are parallel to each other, the incident face and the emission face may be non-parallel as long as an optical signal can be guided from the incident face toward the emission face.

The light pipe 24 is preferably made of a material that easily transmits light in a wavelength band of spatial light. For example, the light pipe 24 can be made of a material of a general optical fiber. The optical signal incident on the incident face of the light pipe 24 is guided to the emission face while being reflected by the side face of the light pipe 24. The optical signal guided to the emission face is emitted from the emission face. Most of the optical signals guided inside the light pipe may be emitted from the emission face, and some of the optical signals may leak when reflected by the side face.

The light-receiving element 25 is disposed behind the light pipe 24. The light-receiving element 25 includes the light-receiving portion 250 that receives the optical signal emitted from the light pipe 24. The light-receiving element 25 is disposed in such a way that the light-receiving portion 250 faces the emission face of the light pipe 24. The optical signal emitted from the light pipe 24 is received by the light-receiving portion 250 of the light-receiving element 25. The light-receiving element 25 converts the received optical signal into an electric signal. The light-receiving element 25 outputs the converted electric signal to a decoder (not illustrated). The light-receiving element 25 has the same configuration as the light-receiving element 15 of the first example embodiment.

When the light pipe 24 is used, an optical signal can be guided toward the light-receiving portion 250 of the light-receiving element 25. Therefore, the area of the light-receiving portion 250 of the light-receiving element 25 can be reduced. Therefore, the light-receiving element 25 having a small light-receiving surface can be applied while having the same light-receiving efficiency. For example, when the light pipe 24 is used, the light-receiving element 25 having high sensitivity can be used while the area of the light-receiving portion 250 is small.

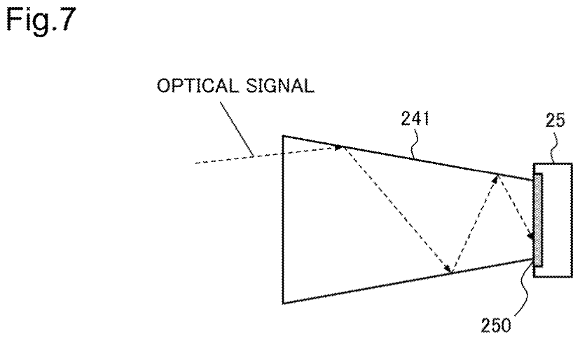

FIG. 7 is a side view of a first example (light pipe 241) of the light pipe 24. The light pipe 241 is formed in a tapered shape in such a way as to be narrowed from the incident face toward the emission face. The light pipe 241 is made of a material that transmits light in a wavelength band of an optical signal. The side face of the light pipe 241 reflects light in a wavelength band of an optical signal. For example, a reflector that reflects light in a wavelength band of an optical signal may be installed outside the side face of the light pipe 241.

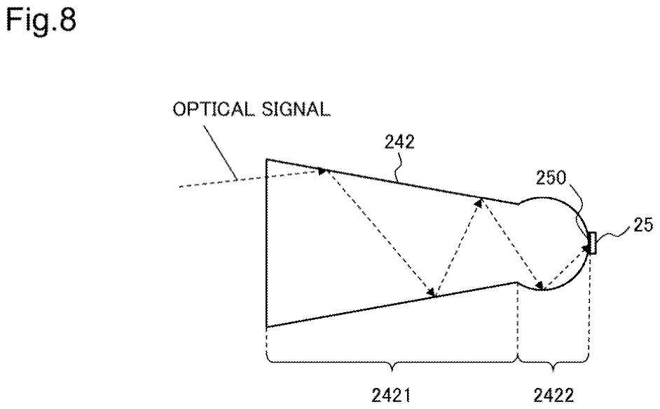

FIG. 8 is a side view of a second example (light pipe 242) of the light pipe 24. The light pipe 242 includes a light guide portion 2421 on the incident side and an emission portion 2422 on the emission side. The light guide portion 2421 and the emission portion 2422 are integrated. The light guide portion 2421 is formed in a tapered shape in such a way as to be narrowed from the incident face toward the emission portion 2422. The emission portion 2422 has a spherical or ellipsoidal shape. The end of the emission portion 2422 (the right end portion of the light pipe 242 in FIG. 8) is an emission face. A connection portion between the light guide portion 2421 and the emission portion 2422 is configured not to affect propagation of an optical signal. In the light pipe 241 (FIG. 7), when the light-receiving element 25 is small, the angle of the taper is steep, and thus, an optical signal is easily radiated from the incident face by reflection on the side face. In the light pipe 242 (FIG. 8), since there is the emission portion 2422, the taper of the light guide portion 2421 may not be steep. Therefore, as compared with the light pipe 241 (FIG. 7), the light pipe 242 (FIG. 8) is more likely to efficiently guide an optical signal to the small light-receiving element 25 of the light-receiving portion 250. The emission portion 2422 may be formed in a shape other than a sphere or an ellipsoid as long as the optical signal entering from the light guide portion 2421 is easily guided toward the emission face. The light pipe 242 is made of a material that transmits light in a wavelength band of an optical signal. A portion other than the side face of the light guide portion 2421 and the emission face of the emission portion 2422 reflects light in the wavelength band of the optical signal. For example, a reflector that reflects light in a wavelength band of an optical signal may be installed on a portion other than the side face of the light pipe 242 and the emission face of the emission portion 2422.

For example, an anti-reflection layer related to a wavelength band of an optical signal may be provided on incident faces of the light pipe 241 and the light pipe 242. When the anti-reflection layer is provided on the incident face, an optical signal reflected by the incident face can be reduced. A color filter that selectively passes light in a wavelength band of an optical signal may be provided on the incident faces of the light pipe 241 and the light pipe 242. When the color filter is provided on the incident face, light in the wavelength band of the optical signal is selectively guided to the light-receiving portion 250 of the light-receiving element 25, so that noise components included in the optical signal can be removed.

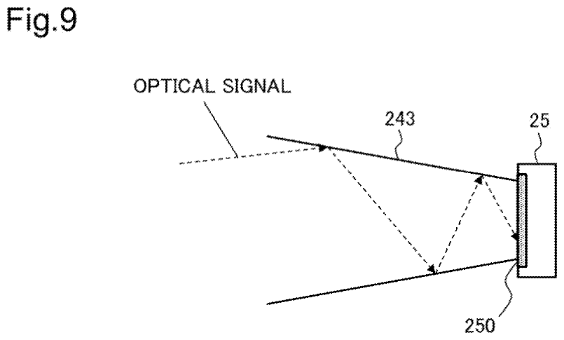

FIG. 9 is a side view of a third example (light pipe 243) of the light pipe 24. The interior of the light pipe 243 is hollow. An incident face and an emission face of the light pipe 243 are opened. The side face of the light pipe 243 reflects light in a wavelength band of an optical signal. For example, a reflector that reflects light in a wavelength band of an optical signal may be installed inside the side face of the light pipe 243. The main body of the light pipe 243 may be made of a material that transmits light in a wavelength band of an optical signal, and a reflector that reflects the optical signal may be installed on a side face of the light pipe 243. The optical signal reflected at the inner side of the light pipe 243 is emitted from the emission face and received by the light-receiving portion 250 of the light-receiving element 25. Since the optical signal is not attenuated inside the light pipe 243, the intensity of the optical signal reaching the light-receiving portion 250 of the light-receiving element 25 is larger than that of the light pipes 241 to 242 (FIGS. 7 to 8).

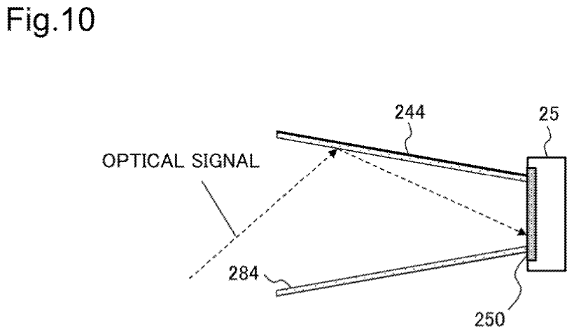

FIG. 10 is a side view of a fourth example (light pipe 244) of the light pipe 24. The interior of the light pipe 244 is hollow. An incident face and an emission face of the light pipe 244 are opened. On the inner side face of the light pipe 244, a directional light guide body 284 that directionally guides light in a wavelength band of an optical signal toward an emission face is disposed. The directional light guide body 284 directionally guides the optical signal incident on the incident face toward the emission face. In FIG. 10, the optical signal is illustrated to be reflected at the surface of the directional light guide body 284. The directional light guide body 284 directionally guides the optical signal toward the emission face by reflecting the light at a reflection angle larger than the incident angle. The optical signal having entered the directional light guide body 284 may be configured to propagate inside the directional light guide body 284 and is emitted from an emission face directed to the light-receiving portion 250 of the light-receiving element 25. In the case of the light pipe 243 (FIG. 9), the optical signal reflected by the inner face may return to the incident face and may not reach the light-receiving element 25. In the light pipe 244 (FIG. 10), the optical signal incident on the incident face is directionally guided toward the light-receiving element 25. Therefore, it is difficult for the optical signal to return to the incident face, and the light-receiving efficiency of the light-receiving element 25 is improved.

For example, the directional light guide body 284 has a reflection structure including at least one reflection surface that reflects the optical signal incident on the incident face toward the emission face. The reflection structure is formed of a material that reflects light in a wavelength band of an optical signal. For example, the reflection structure can be formed of a material such as metal. The material of the reflection structure is not particularly limited as long as light in the wavelength band of the optical signal can be reflected.

For example, the directional light guide body 284 may be achieved by a reflection type diffraction grating (also referred to as a diffraction grating array) having a structure in which a plurality of gratings having a height on the order of micrometers is disposed. The diffraction grating array diffracts the optical signal in such a way that the optical signal incident on the upper face of the directional light guide body 284 travels toward the emission face. For example, the diffraction grating array can be achieved by a blazed diffraction grating or a holographic diffraction grating. The grating intervals of the diffraction grating array is preferably adjusted in such a way that the optical signal travels toward the emission face.

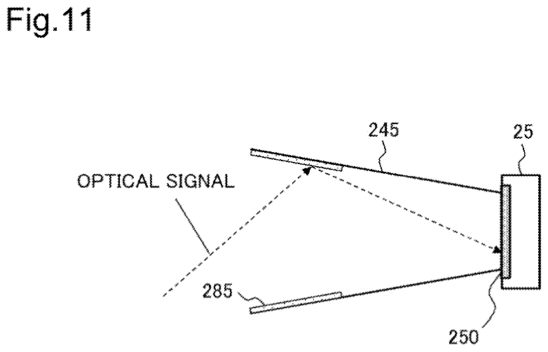

FIG. 11 is a side view of a fifth example (light pipe 245) of the light pipe 24. The interior of the light pipe 245 is hollow. An incident face and an emission face of the light pipe 245 are opened. On the inner side face of the light pipe 245 toward the incident face, a directional light guide body 285 that directionally guides light in a wavelength band of an optical signal toward the emission face is disposed. The directional light guide body 285 has the same configuration as the directional light guide body 284 of the fourth example (FIG. 10). As in the third example (FIG. 9), the light of the wavelength band of the optical signal is reflected on the inner side face of the light pipe 245 toward the emission face. For example, a reflector that reflects light in a wavelength band of an optical signal may be installed inside the light pipe 243 toward the emission face. The directional light guide body 285 directionally guides the optical signal incident on the incident face toward the emission face, as in the fourth example (FIG. 10). The directional light guide body 285 directionally guides the optical signal toward the emission face by reflecting the light at a reflection angle larger than the incident angle. The optical signal emitted from the directional light guide body 285 is reflected at the inner side of the light pipe 245 toward the emission face and emitted from the emission face. The optical signal emitted from the emission face is received by the light-receiving portion 250 of the light-receiving element 25. When the incident angle of the optical signal with respect to the normal line of the incident face is large, there is a possibility that the optical signal reflected several times at the inner side of the light pipe 245 returns to the incident face. Since the optical signal incident on the light pipe 245 first enters the directional light guide body 285 and is guided directionally toward the light-receiving portion 250, the possibility of returning to the incident face is reduced.

The examples of FIGS. 7 to 11 are merely examples, and the configuration of the light pipe 24 is not limited to these forms. For example, the light pipe may be configured by combining the configurations of FIGS. 7 to 11 in any manner.

As described above, the light-receiving device of the present example embodiment includes the condenser lens, the beam control element, the light pipe, and the light-receiving element. The condenser lens receives a spatial optical signal. The beam control element emits an optical signal derived from the spatial optical signal condensed by the condenser lens toward a predetermined region. The light pipe guides the optical signal emitted from the beam control element, to a light-receiving portion disposed at a predetermined region. For example, the light pipe has a hollow structure, and includes a directional light guide body that directionally guides an optical signal toward a light-receiving portion disposed at a predetermined region where the directional light guide is located, on an inner face of the light pipe, at least in a vicinity of an incident face. The light-receiving element is disposed with the light-receiving portion facing a predetermined region. The light-receiving element receives an optical signal.

According to the light-receiving device of the present example embodiment, by guiding the optical signal condensed by the condenser lens to the light-receiving portion of the light-receiving element via the light pipe, the optical signal derived from the spatial optical signal can be more efficiently received.

### Third Example Embodiment

Next, a light-receiving device according to the third example embodiment will be described with reference to the drawings. The light-receiving device of the present example embodiment is used in a situation where the direction from which the spatial optical signal comes is limited to some extent. The light-receiving device of the present example embodiment includes a beam control element having an elongated shape set in conformance to an incoming direction of a spatial optical signal. In the present example embodiment, the incoming direction of the spatial optical signal is limited to the horizontal direction, and the shape of the beam control element is elongated in the horizontal direction in conformance to the incoming direction. The light-receiving device of the present example embodiment may be combined with the light pipe of the second example embodiment.

(Configuration)

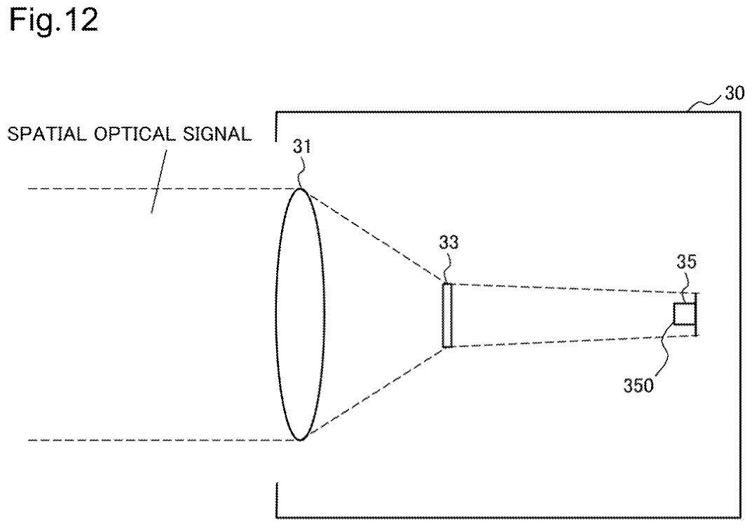

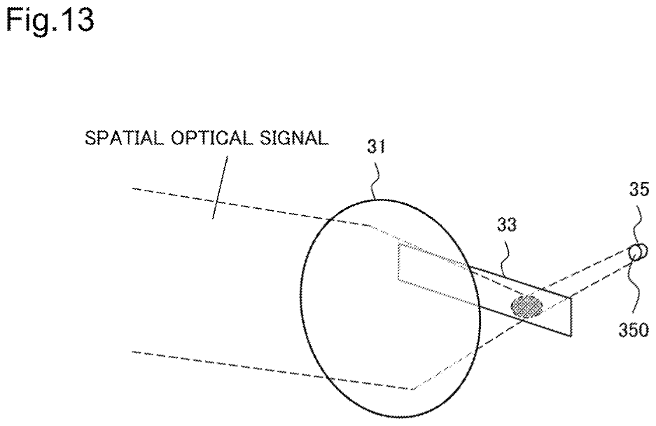

FIG. 12 is a conceptual diagram illustrating an example of a configuration of a light-receiving device 30 of the present example embodiment. The light-receiving device 30 includes a condenser lens 31, a beam control element 33, and a light-receiving element 35. FIG. 12 is a view of the internal configuration of the light-receiving device 30 when viewed from the lateral direction. FIG. 13 is a conceptual diagram for describing an example of a trajectory of light received by the light-receiving device 30. FIG. 13 is a perspective view of the internal configuration of the light-receiving device 30 when viewed obliquely from the front.

The condenser lens 31 is an optical element that condenses a spatial optical signal coming from the outside. The optical signal condensed by the condenser lens 31 is condensed toward the incident face of the beam control element 33. The condenser lens 31 has the same configuration as the condenser lens 11 of the first example embodiment. The condenser lens 31 may be configured to condense light in accordance with the shape of the beam control element 33.

Light beam control element 33 is disposed behind the condenser lens 31. The beam control element 33 is disposed in such a way that the incident face faces an emission face of the condenser lens 31. The beam control element 33 is set in a shape conforming to the incoming direction of the spatial optical signal. For example, in a case where the spatial optical signal comes from the horizontal direction, the beam control element 33 is set in a shape having a long axis in the horizontal direction and a short axis in the vertical direction. For example, when the spatial optical signal comes from a direction (hereinafter, referred to as a vertical direction) perpendicular to the horizontal plane, the beam control element 33 is set in a shape having a long axis in the vertical direction and a short axis in the horizontal direction. The shape of the beam control element 33 may be set in conformance to the incoming direction of the spatial optical signal.

The optical signal incident on the incident face of the beam control element 33 is emitted toward a predetermined region with a close distance. An emission direction of the optical signal incident on the incident face of the beam control element 33 is controlled, and the optical signal is emitted toward a light-receiving portion 350 of the light-receiving element 35. The beam control element 33 has the same configuration as the beam control element 13 of the first example embodiment except for the shape.

The light-receiving element 35 is disposed behind the beam control element 33. The light-receiving element 35 includes the light-receiving portion 350 that receives the optical signal emitted from the beam control element 33. The light-receiving element 35 is disposed in such a way that light-receiving portion 350 faces the emission face of the beam control element 33. The optical signal emitted from the beam control element 33 is received by the light-receiving portion 350 of the light-receiving element 35. The light-receiving element 35 converts the received optical signal into an electric signal. The light-receiving element 35 outputs the converted electric signal to a decoder (not illustrated). The light-receiving element 35 has the same configuration as the light-receiving element 15 of the first example embodiment.

As described above, the light-receiving device of the present example embodiment includes the condenser lens, the beam control element, and the light-receiving element. The condenser lens receives a spatial optical signal. The beam control element has a shape conforming to the incoming direction of the spatial optical signal. The beam control element emits an optical signal derived from the spatial optical signal condensed by the condenser lens toward a predetermined region. The light-receiving element is disposed with the light-receiving portion facing a predetermined region. The light-receiving element receives an optical signal.

According to the light-receiving device of the present example embodiment, it is possible to efficiently receive the spatial optical signal having a limited incoming direction by using the beam control element having a shape conforming to the incoming direction of the spatial optical signal. For example, in a case where the incoming direction of the spatial optical signal from the communication target is limited to the horizontal direction, the vertical direction, or the like, it is not necessary to receive light coming from a direction different from these directions. In the present example embodiment, the incoming direction of the spatial optical signal is limited to the horizontal direction, and the shape of the beam control element is elongated along the horizontal direction in conformance to the incoming direction. If the incoming direction of the spatial optical signal is limited to the vertical direction, the shape of the beam control element may be elongated along the vertical direction in conformance to the incoming direction. Light coming from a direction different from the incoming direction of the spatial optical signal from the communication target can be regarded as a noise component or a disturbance component. Therefore, according to the present example embodiment, since the light of the noise component or the disturbance component is not received, the spatial optical signal from the communication target can be more efficiently received.

### Fourth Example Embodiment

Next, a light-receiving device according to the fourth example embodiment will be described with reference to the drawings. The light-receiving device of the present example embodiment includes a beam control element that diffracts the optical signal condensed by the condenser lens, reflects the optical signal to a predetermined region, and guides the optical signal. In the present example embodiment, an example including a beam control element having an elongated shape set in conformance to an incoming direction of a spatial optical signal will be described, but a beam control element (first example embodiment) capable of coping with a spatial optical signal coming from any direction may be applied. The light-receiving device of the present example embodiment may be combined with the light pipe of the second example embodiment.

(Configuration)

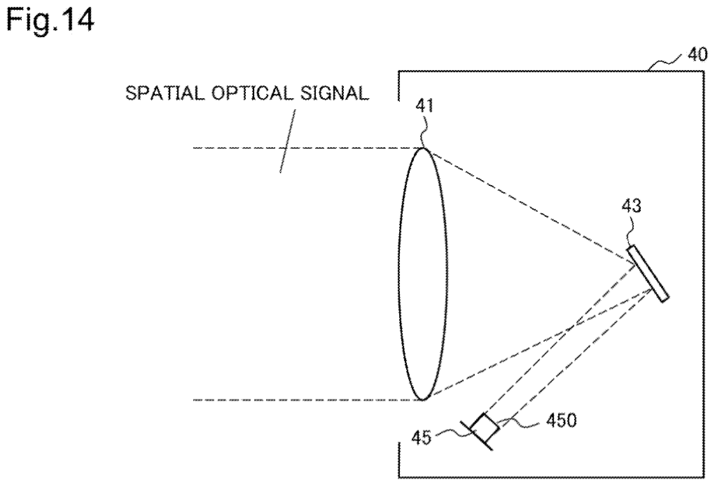

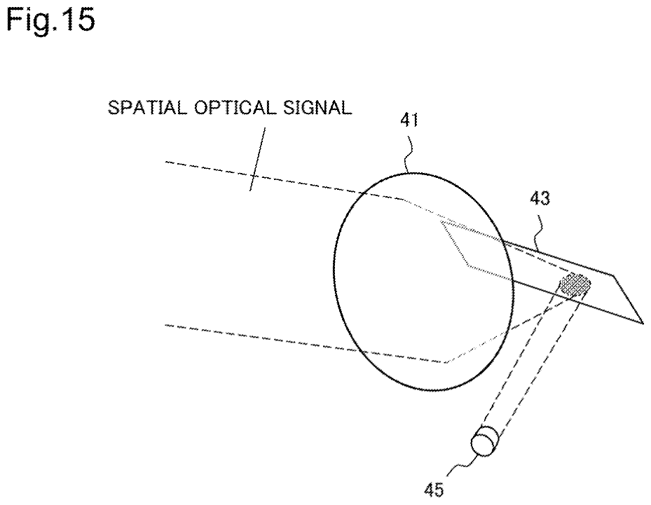

FIG. 14 is a conceptual diagram illustrating an example of a configuration of a light-receiving device 40 of the present example embodiment. The light-receiving device 40 includes a condenser lens 41, a beam control element 43, and a light-receiving element 45. FIG. 14 is a view of the internal configuration of the light-receiving device 40 when viewed from the lateral direction. FIG. 15 is a conceptual diagram for describing an example of a trajectory of light received by the light-receiving device 40. FIG. 15 is a perspective view of the internal configuration of the light-receiving device 40 when viewed obliquely from the front.

The condenser lens 41 is an optical element that condenses a spatial optical signal coming from the outside. The optical signal condensed by the condenser lens 41 is condensed toward the incident face of the beam control element 43. The condenser lens 41 has the same configuration as the condenser lens 11 of the first example embodiment. The condenser lens 41 may be configured to condense light in accordance with the shape of the beam control element 43.

Light beam control element 43 is disposed behind the condenser lens 41. The beam control element 43 is a reflection type diffractive optical element. The beam control element 43 has a reflection surface that diffracts and reflects light in a wavelength band of an optical signal. For example, the beam control element 43 is achieved by liquid crystal on silicon (LCOS). For example, the base material of the beam control element 43 is quartz. For example, a reflection layer formed of silicon, gold, or the like is formed on the reflection surface of the beam control element 43. If the wavelength band of the spatial optical signal is in the infrared region, the reflection layer formed on the reflection surface of the beam control element 43 is preferably formed of gold. The reflection surface of the beam control element 43 is disposed in such a way that the optical signal output from condenser lens 41 is reflected toward the light-receiving portion 450 of light-receiving element 45. The beam control element 43 is set in a shape conforming to the incoming direction of the spatial optical signal. For example, when the spatial optical signal comes from the horizontal direction, the beam control element 43 is set in a shape having a long axis in the horizontal direction and a short axis in the vertical direction. For example, when the spatial optical signal comes from the vertical direction, the beam control element 43 is set in a shape having a long axis in the vertical direction and a short axis in the horizontal direction. The shape of the beam control element 43 may be set in conformance to the incoming direction of the spatial optical signal. In the case of being configured to cope with a spatial optical signal coming from any direction, the shape of the beam control element 43 is not particularly limited.

The optical signal condensed by the condenser lens 41 is incident on the reflection surface of the beam control element 43. The optical signal incident on the reflection surface of the beam control element 43 is diffracted and reflected toward a predetermined region with a close distance. The traveling direction of the optical signal diffracted/reflected by the reflection surface of the beam control element 43 is controlled, and the optical signal is emitted toward a light-receiving portion 450 of the light-receiving element 45.

The light-receiving element 45 is disposed behind the beam control element 43. The light-receiving element 45 includes the light-receiving portion 450 that receives the optical signal reflected by the beam control element 43. The light-receiving element 45 is disposed in such a way that the optical signal reflected by the beam control element 43 is received by the light-receiving portion 450. The optical signal reflected by the beam control element 43 is received by the light-receiving portion 450 of the light-receiving element 45. The light-receiving element 45 converts the received optical signal into an electric signal. The light-receiving element 45 outputs the converted electric signal to a decoder (not illustrated). The light-receiving element 45 has the same configuration as the light-receiving element 15 of the first example embodiment.

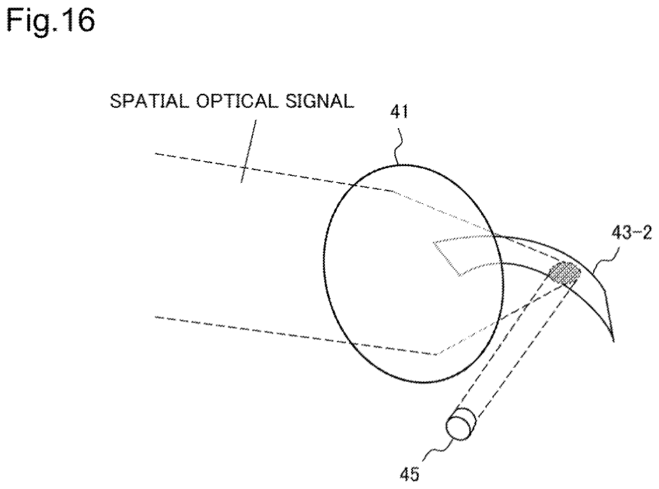

FIG. 16 is a conceptual diagram for describing a modification example of the light-receiving device 40 of the present example embodiment. The light-receiving device of the modification example of FIG. 16 includes a beam control element 43-2 curved in a curved shape. The beam control element 43-2 is curved in accordance with a curved surface or a curved line where the position of the light-receiving portion 450 of the light-receiving element 45 is a focal point. An optical signal incident on a position away from the center of the beam control element 43 (FIG. 15) is not reflected toward the position (predetermined region) of the light-receiving portion 450 of the light-receiving element 45, and thus is not received by the light-receiving element 45. On the other hand, since the beam control element 43-2 (FIG. 16) has a curved shape, an optical signal is incident on the incident face at an angle close to normal incidence. Therefore, in the beam control element 43-2 (FIG. 16), an optical signal incident on a position away from the center is also reflected toward the position (predetermined region) of the light-receiving portion 450 of the light-receiving element 45, and thus can be received by the light-receiving element 45. That is, compared with the beam control element 43 (FIG. 15), the beam control element 43-2 (FIG. 16) can condense a wider range of optical signals on the light-receiving portion 450 of the light-receiving element 45.

As described above, the light-receiving device of the present example embodiment includes the condenser lens, the beam control element, and the light-receiving element. The condenser lens receives a spatial optical signal. The beam control element is a reflection type diffractive optical element that reflects the optical signal condensed by the condenser lens toward a predetermined region. The beam control element is a reflection type diffractive optical element that diffracts and reflects an optical signal derived from the spatial optical signal condensed by the condenser lens toward a predetermined region. For example, the beam control element has a curved shape having a focal point in a predetermined region. The light-receiving element is disposed with the light-receiving portion facing a predetermined region. The light-receiving element receives an optical signal.

According to the light-receiving device of the present example embodiment, the optical signal condensed by the condenser lens is reflected by the beam control element in such a way as to be guided to the predetermined region, whereby the spatial optical signal coming from any direction can be efficiently received.

### Fifth Example Embodiment

Next, a light-receiving device of the fifth example embodiment will be described with reference to the drawings. A light-receiving device of the present example embodiment includes a fiber bundle that guides an optical signal emitted from a beam control element to a light-receiving portion of the light-receiving element. The fiber bundle is a member that guides the optical signal emitted from the beam control element to the light-receiving portion of the light-receiving element.

(Configuration)

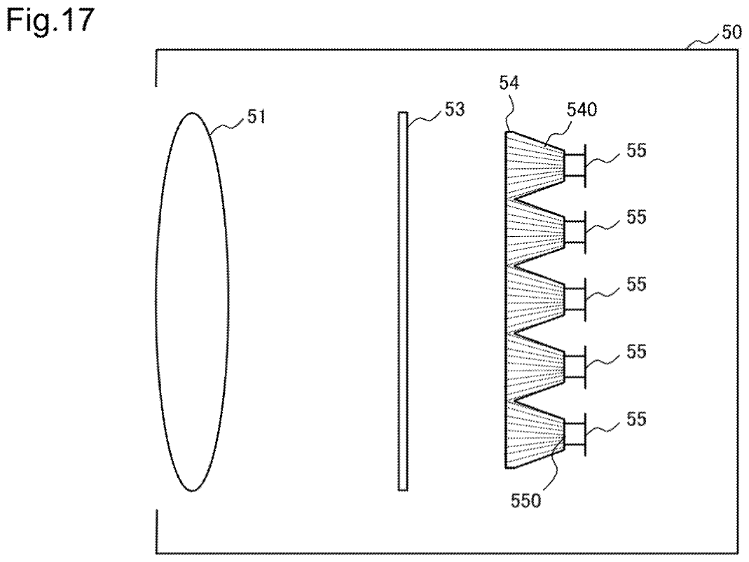

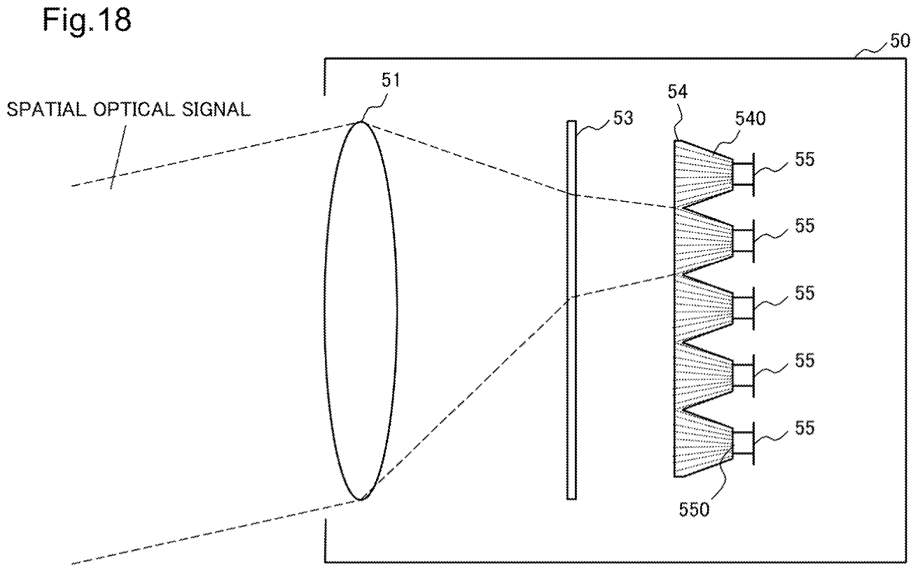

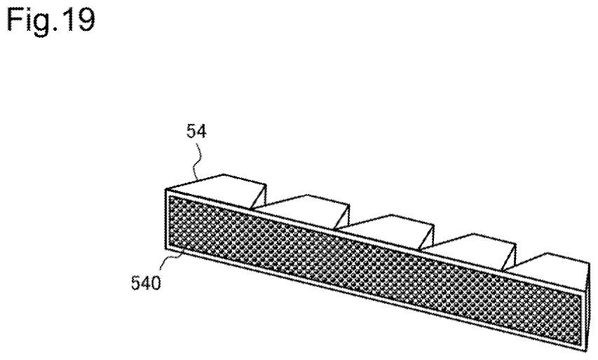

FIG. 17 is a conceptual diagram illustrating an example of a configuration of a light-receiving device 50 of the present example embodiment. The light-receiving device 50 includes a condenser lens 51, a beam control element 53, a fiber bundle 54, and a light-receiving element 55. FIG. 17 is a view of the internal configuration of the light-receiving device 50 when viewed from the lateral direction. FIG. 18 is a conceptual diagram for describing an example of a trajectory of light received by the light-receiving device 50. FIG. 19 is a perspective view of the fiber bundle 54 included in the light-receiving device 50 when viewed obliquely from the front.

The condenser lens 51 is an optical element that condenses a spatial optical signal coming from the outside. The optical signal condensed by the condenser lens 51 is condensed toward the incident face of the beam control element 53. The condenser lens 51 has the same configuration as the condenser lens 11 of the first example embodiment.

Light beam control element 53 is disposed behind the condenser lens 51. The beam control element 53 is disposed in such a way that the incident face faces an emission face of the condenser lens 51. The optical signal incident on the incident face of the beam control element 53 is emitted toward a predetermined region with a close distance. An emission direction of the optical signal incident on the incident face of the beam control element 53 is controlled, and the optical signal is emitted toward the incident face of the fiber bundle 54. The beam control element 53 has the same configuration as the beam control element 13 of the first example embodiment.

The fiber bundles 54 are provided in association with the plurality of light-receiving elements 55. The fiber bundle 54 has a structure in which a plurality of optical fibers 540 is bundled. The fiber bundle 54 has an incident face on which the spatial optical signal is incident and an emission face from which the optical signal guided inside the fiber bundle 54 emits. The incident ends of the plurality of optical fibers 540 are disposed on the incident face of the fiber bundle 54. The emission ends of the plurality of optical fibers 540 are disposed on the emission face of the fiber bundle 54. A bundle of the optical fibers 540 constituting the fiber bundle 54 is disposed in association with each of the plurality of light-receiving elements 55. The fiber bundle 54 may be configured to be associated with a single light-receiving element 55.

The fiber bundle 54 is disposed in such a way that the incident face is located at a predetermined region irradiated with the optical signal emitted from the beam control element 53. The emission face of the fiber bundle 54 is disposed in such a way as to be in contact with the light-receiving portion 550 of each of the plurality of associated light-receiving elements 55. The emission face of the fiber bundle 54 and the light-receiving portion 550 of the light-receiving element 55 need not be in contact with each other as long as the optical signal emitted from the emission face of the fiber bundle 54 is incident on the light-receiving portion 550 of the light-receiving element 55. Although FIG. 17 illustrates an example in which the incident face and the emission face are parallel to each other, the incident face and the emission face may be non-parallel as long as an optical signal can be guided from the incident face toward the emission face.

The bundle of the plurality of optical fibers 540 is bundled in such a way as to be tapered from the incident face to the emission face of the fiber bundle 54 toward the light-receiving portion 550 of the associated light-receiving element 55. The plurality of optical fibers 540 may be linearly disposed or may be disposed in a curved shape from the incident end to the emission end. The optical fiber 540 constituting the fiber bundle 54 may have the same diameter at the incident end and the emission end, or may have different diameters at the incident end and the emission end. For example, the optical fiber 540 constituting the fiber bundle 54 may have an emission end with a diameter smaller than that of an incident end.

The optical fiber 540 is preferably made of a material that easily transmits light in a wavelength band of spatial light. For example, the optical fiber 540 can be made of a material of a general optical fiber. For example, the incident end of the optical fiber 540 may be antireflection coated in such a way that light in a frequency band of an optical signal is hardly reflected. The optical signal incident on the incident face of the fiber bundle 54 is guided to the emission face while being totally reflected by the side face of the optical fiber 540 constituting the fiber bundle 54. The optical signal guided to the emission face is emitted toward the light-receiving portion 550 of the light-receiving element 55. Since the optical signal guided inside the optical fiber 540 constituting the fiber bundle 54 does not leak from the side face of the optical fiber 540, most of the optical signal is emitted from the emission face.

The light-receiving element 55 is disposed behind the fiber bundle 54. The light-receiving element 55 includes a light-receiving portion 550 that receives the optical signal emitted from the fiber bundle 54. The light-receiving element 55 is disposed in such a way that the light-receiving portion 550 faces the emission face of the fiber bundle 54. The optical signal emitted from the fiber bundle 54 is received by the light-receiving portion 550 of the light-receiving element 55. The light-receiving element 55 converts the received optical signal into an electric signal. The light-receiving element 55 outputs the converted electric signal to a decoder (not illustrated). The light-receiving element 55 has the same configuration as the light-receiving element 15 of the first example embodiment.

When the fiber bundle 54 is used, an optical signal can be guided toward the light-receiving portion 550 of the light-receiving element 55. Therefore, the area of the light-receiving portion 550 of the light-receiving element 55 can be reduced. Therefore, the light-receiving element 55 having a small light-receiving surface can be applied while having the same light-receiving efficiency. For example, when the fiber bundle 54 is used, the light-receiving element 55 having high sensitivity can be used while the area of the light-receiving portion 550 is small.

### Modification Example

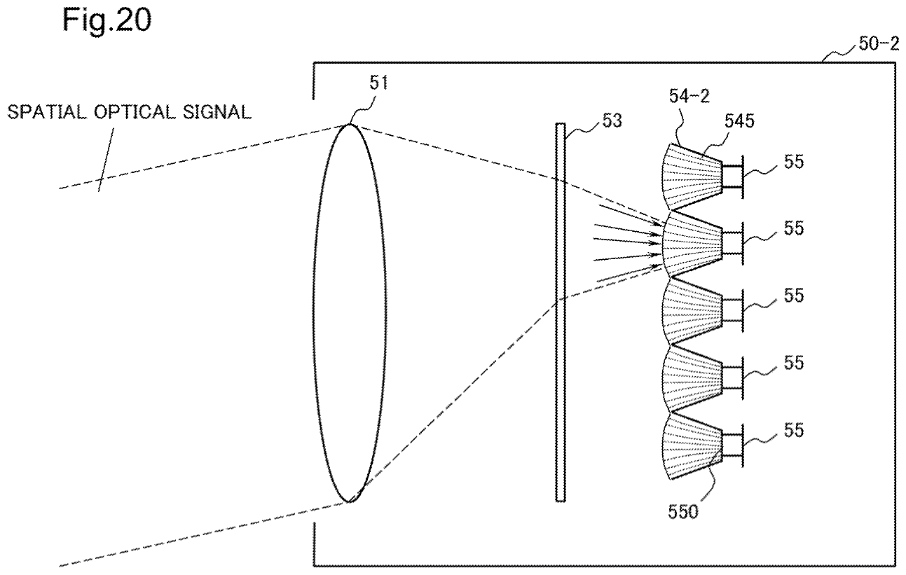

FIG. 20 is a conceptual diagram illustrating an example of a configuration of a light-receiving device 50-2 of a modification example of the present example embodiment. The light-receiving device 50-2 includes the condenser lens 51, the beam control element 53, a fiber bundle 54-2, and the light-receiving element 55. FIG. 20 is a view of the internal configuration of the light-receiving device 50 when viewed from the lateral direction. In FIG. 20, a conceptual traveling direction (optical axis) of the optical signal emitted from the beam control element 53 and traveling toward the emission face of the fiber bundle 54-2 is indicated by an arrow. The light-receiving device 50-2 of the present modification example is different from the light-receiving device 50 in the configuration of the plurality of optical fibers 545 included in the fiber bundle 54-2.

Fiber bundle 54-2 includes a plurality of optical fibers 545. The fiber bundle 54-2 has a structure in which a plurality of optical fibers 545 is bundled. The plurality of optical fibers 545 is disposed in such a way that the optical axis of the optical signal emitted from the beam control element 53 is incident on the cross section of the incident end disposed on the incident face of the fiber bundle 54-2 from a substantially perpendicular direction. For example, the plurality of optical fibers 545 is disposed in such a way as to draw a smooth curve from the incident end to the emission end. The optical signals entering the incident ends of the plurality of optical fibers 545 travel inside the plurality of optical fibers 545 toward the emission ends, and are emitted from the emission ends of the plurality of optical fibers 545. The optical signals emitted from the emission ends of the plurality of optical fibers 545 are received by the light-receiving element 55.

An optical signal obliquely incident on the cross section of the incident end of the optical fiber 545 is easily reflected at the incident end. In the present modification example, the optical fiber 545 is disposed in such a way that the incident direction of the optical signal emitted from the beam control element 53 is substantially perpendicular to the cross section of the incident end of the optical fiber 545. Therefore, according to the present modification example, the ratio of reflection of the optical signal at the incident end of the optical fiber 545 is reduced, and the optical signal easily enters the incident end of the optical fiber 545. Therefore, according to the present modification example, the light-receiving efficiency by the light-receiving element 55 is improved.

As described above, the light-receiving device of the present example embodiment includes the condenser lens, the beam control element, the fiber bundle, and the light-receiving element. The condenser lens receives a spatial optical signal. The beam control element emits an optical signal derived from the spatial optical signal condensed by the condenser lens toward a predetermined region. The fiber bundle includes a bundle of a plurality of optical fibers that guides an optical signal emitted from the beam control element, to a light-receiving portion disposed at a predetermined region. For example, each of the plurality of optical fibers included in the fiber bundle is disposed in such a way that the cross section of the incident ends of the plurality of optical fibers is substantially perpendicular to the optical axis of the optical signal emitted from the beam control element. The light-receiving element is disposed with the light-receiving portion facing a predetermined region. The light-receiving element receives an optical signal.

According to the light-receiving device of the present example embodiment, by guiding the optical signal condensed by the condenser lens to the light-receiving portion of the light-receiving element via the fiber bundle, the optical signal derived from the spatial optical signal can be more efficiently received.

### Sixth Example Embodiment

Next, a light-receiving device according to the sixth example embodiment will be described with reference to the drawings. A light-receiving device of the present example embodiment includes a decoder that decodes an optical signal received by a light-receiving element. In the present example embodiment, an example including a beam control element having an elongated shape set in conformance to an incoming direction of a spatial optical signal will be described, but a beam control element capable of coping with a spatial optical signal coming from any direction may be applied. As in the fourth example embodiment, the reflection type beam control element may be applied to the light-receiving device of the present example embodiment. The light-receiving device of the present example embodiment may be combined with the light pipe of the second example embodiment and the fiber bundle of the fifth example embodiment.

(Configuration)

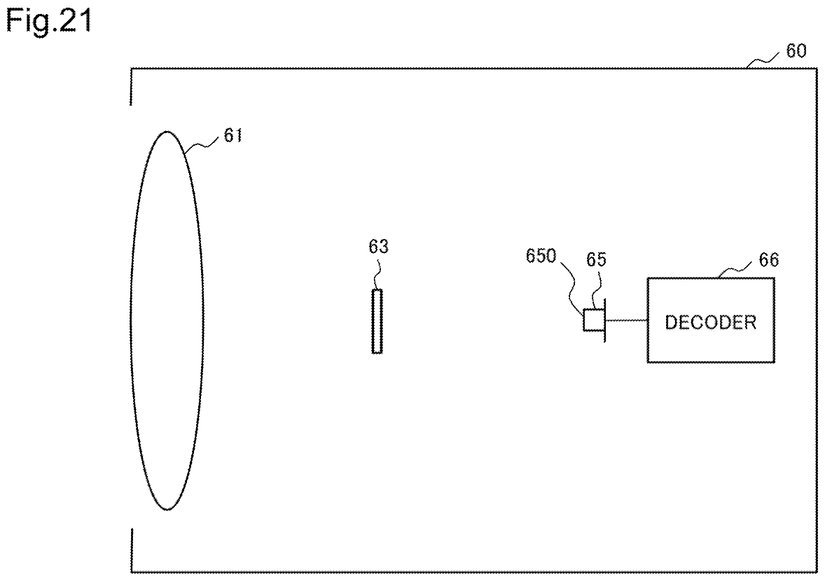

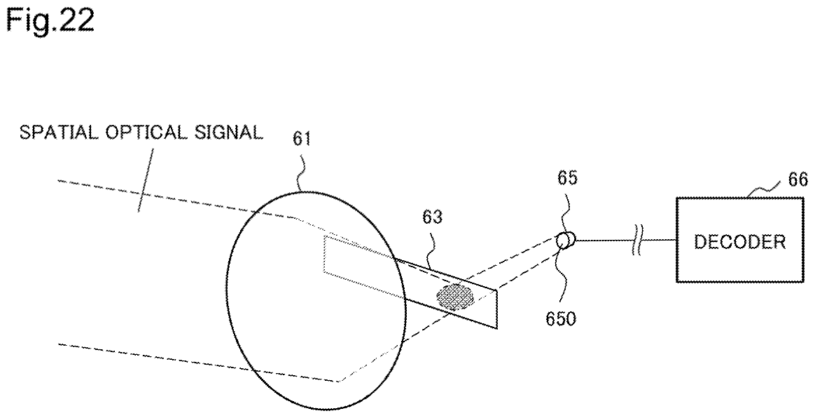

FIG. 21 is a conceptual diagram illustrating an example of a configuration of a light-receiving device 60 of the present example embodiment. The light-receiving device 60 includes a condenser lens 61, a beam control element 63, a light-receiving element 65, and a decoder 66. FIG. 21 is a view of the internal configuration of the light-receiving device 60 when viewed from the lateral direction. FIG. 22 is a conceptual diagram for describing an example of a trajectory of light received by the light-receiving device 60. FIG. 22 is a perspective view of the internal configuration of the light-receiving device 60 when viewed obliquely from the front. The position of the decoder 66 is not particularly limited. The decoder 66 may be disposed inside the light-receiving device 60 or may be disposed outside the light-receiving device 60.

The condenser lens 61 is an optical element that condenses a spatial optical signal coming from the outside. The optical signal condensed by the condenser lens 61 is condensed toward the incident face of the beam control element 63. The condenser lens 61 has the same configuration as the condenser lens 11 of the first example embodiment. The condenser lens 61 may be configured to condense the optical signal in accordance with the shape of the beam control element 63.

Light beam control element 63 is disposed behind the condenser lens 61. The beam control element 63 is disposed in such a way that the incident face faces an emission face of the condenser lens 61. For example, as in the third example embodiment, the beam control element 63 is set in a shape conforming to the incoming direction of the spatial optical signal. The beam control element 63 may be configured to cope with a spatial optical signal coming from any direction as in the first example embodiment. The beam control element 63 may be a reflection type as in the fourth example embodiment. Since the beam control element 63 is similar to any of the first to fifth example embodiments, a detailed description thereof will be omitted.

The light-receiving element 65 is disposed behind the beam control element 63. The light-receiving element 65 includes a light-receiving portion 650 that receives the optical signal emitted from the beam control element 63. The light-receiving element 65 is disposed in such a way that light-receiving portion 650 faces the emission face of the beam control element 63. The optical signal emitted from the beam control element 63 is received by the light-receiving portion 650 of the light-receiving element 65. The light-receiving element 65 converts the received optical signal into an electric signal (hereinafter, also referred to as a signal). The light-receiving element 65 outputs the converted signal to the decoder 66. The light-receiving element 65 has the same configuration as the light-receiving element 15 of the first example embodiment.

The decoder 66 acquires a signal output from the light-receiving element 65. The decoder 66 amplifies the signal from the light-receiving element 65. The decoder 66 decodes the amplified signal and analyzes a signal from the communication target. The signal decoded by the decoder 66 is used for any purpose. The use of the signal decoded by the decoder 66 is not particularly limited.

[Decoder]

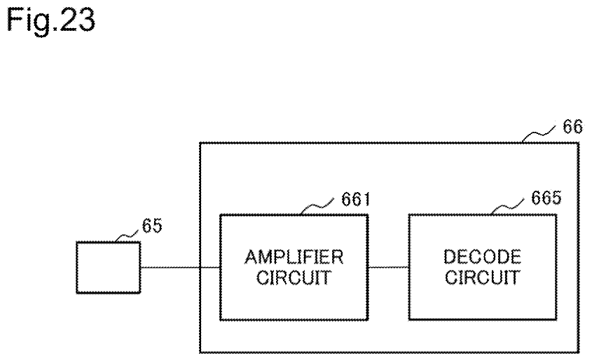

Next, an example of a detailed configuration of the decoder 66 included in the light-receiving device 60 will be described with reference to the drawings. FIG. 23 is a block diagram illustrating an example of a configuration of the decoder 66. The decoder 66 includes an amplifier circuit 661 and a decode circuit 665.

The amplifier circuit 661 acquires a signal from the light-receiving element 65. The amplifier circuit 661 amplifies the selected signal. The amplifier circuit 661 may selectively pass a signal in a wavelength band of the spatial optical signal. For example, the amplifier circuit 661 may cut a signal derived from ambient light such as sunlight among the acquired signals and selectively pass a signal of a high frequency component corresponding to the wavelength band of the spatial optical signal. The amplifier circuit 661 outputs the amplified signal to the decode circuit 665.

The decode circuit 665 acquires a signal from the amplifier circuit 661. The decode circuit 665 decodes the acquired signal. The decode circuit 665 may be configured to perform some signal processing on the decoded signal, or may be configured to output the signal to an external signal processing device or the like (not illustrated). In the case of decoding a plurality of signals derived from spatial light from a plurality of communication targets, the second processing circuit may be configured to read the signals in a time division manner.

As described above, the light-receiving device of the present example embodiment includes the condenser lens, the beam control element, the light-receiving element, and the decoder. The condenser lens receives a spatial optical signal. The beam control element emits an optical signal derived from the spatial optical signal condensed by the condenser lens toward a predetermined region. For example, the beam control measure is a near-field diffractive optical element that diffracts the optical signal condensed by the condenser lens toward a predetermined region. The light-receiving element is disposed with the light-receiving portion facing a predetermined region. The light-receiving element receives an optical signal. The decoder decodes a signal based on the optical signal received by the light-receiving element.

According to the light-receiving device of the present example embodiment, a signal based on a spatial optical signal coming from any direction can be decoded. For example, according to the light-receiving device of the present example embodiment, a single-channel receiving device can be achieved. For example, according to the light-receiving device of the present example embodiment, a multichannel receiving device can be achieved by decoding a signal based on a spatial optical signal in a time division manner.

### Seventh Example Embodiment

Next, a light-receiving device according to the seventh example embodiment will be described with reference to the drawings. The light-receiving device of the present example embodiment includes a decoder that decodes the optical signal received by the light-receiving element. In the present example embodiment, an example including a beam control element having an elongated shape set in conformance to an incoming direction of a spatial optical signal will be described, but a beam control element capable of coping with a spatial optical signal coming from any direction may be applied. As in the fourth example embodiment, the reflection type beam control element may be applied to the light-receiving device of the present example embodiment. The light-receiving device of the present example embodiment may be combined with the light pipe of the second example embodiment and the fiber bundle of the fifth example embodiment.

(Configuration)

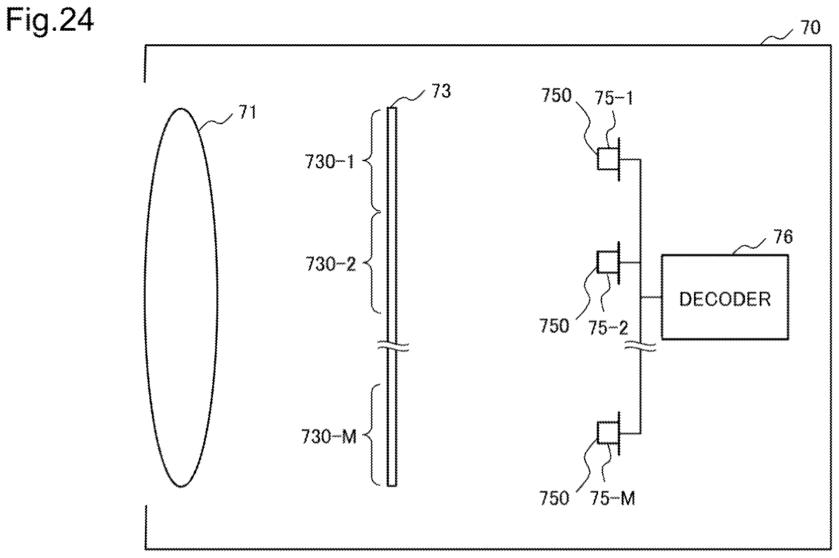

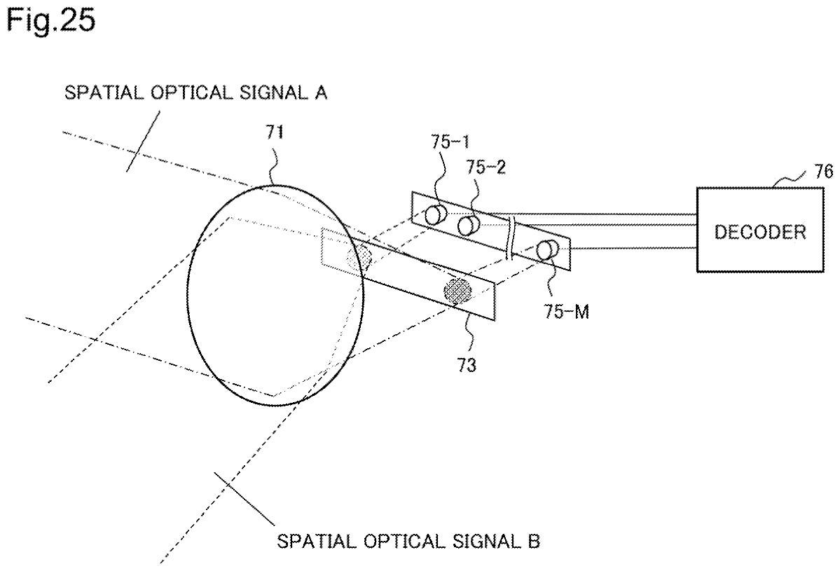

FIG. 24 is a conceptual diagram illustrating an example of a configuration of a light-receiving device 70 of the present example embodiment. The light-receiving device 70 includes a condenser lens 71, a beam control element 73, a plurality of light-receiving elements 75-1 to M (M is a natural number equal to or more than 2), and a decoder 76. FIG. 24 is a plan view of the internal configuration of the light-receiving device 70 when viewed from above. FIG. 25 is a conceptual diagram for describing an example of a trajectory of light received by the light-receiving device 70. FIG. 25 is a perspective view of the internal configuration of the light-receiving device 70 when viewed obliquely from the front. The position of the decoder 76 is not particularly limited. The decoder 76 may be disposed inside the light-receiving device 70 or may be disposed outside the light-receiving device 70.

The condenser lens 71 is an optical element that condenses a spatial optical signal coming from the outside. The optical signal condensed by the condenser lens 71 is condensed toward the incident face of the beam control element 73. The condenser lens 71 has the same configuration as the condenser lens 11 of the first example embodiment. The condenser lens 71 may be configured to condense light in accordance with the shape of the beam control element 73.

Light beam control element 73 is disposed behind the condenser lens 71. The beam control element 73 is disposed in such a way that the incident face faces an emission face of the condenser lens 71. For example, as in the third example embodiment, the beam control element 73 is set in a shape conforming to the incoming direction of the spatial optical signal. The beam control element 73 may be configured to cope with a spatial optical signal coming from any direction as in the first example embodiment. The beam control element 73 may be a reflection type as in the fourth example embodiment.

The optical signal condensed by the condenser lens 71 is incident on the incident face of the beam control element 73. A plurality of beam control regions 730-1 to M is set for the beam control element 73. The plurality of beam control regions 730-1 to M set for the beam control element 73 is associated with the plurality of respective light-receiving elements 75-1 to M. The optical signals incident on the plurality of beam control regions 730-1 to M are emitted toward predetermined regions where the light-receiving portions 750 of the light-receiving elements 75-1 to M related to the respective beam control regions 730 are disposed.

In the example of FIG. 25, the spatial optical signal A and the spatial optical signal B coming from different directions are incident on the condenser lens 71. The optical signals derived from the spatial optical signal A and the spatial optical signal B are condensed by the condenser lens 71 and are incident on different beam control regions 730 of the beam control element 73. The beam control element 13 emits optical signals incident on different beam control regions 730 toward predetermined regions associated with respective beam control regions 730. As a result, the optical signals derived from the spatial optical signal A and the spatial optical signal B are received by different light-receiving elements 75.

The plurality of light-receiving elements 75-1 to M is disposed behind the beam control element 73. Each of the plurality of light-receiving elements 75-1 to M includes the light-receiving portion 750 that receives the optical signal emitted from the beam control element 73. The plurality of light-receiving elements 75-1 to M is disposed in such a way that the emission face of the beam control element 73 and the light-receiving portions 750 face each other. The light-receiving portions 750 of the plurality of light-receiving elements 75-1 to M are disposed to face the plurality of beam control regions 730-1 to M, respectively. The optical signals emitted from the plurality of beam control regions 730-1 to M of the beam control element 73 are received by the light-receiving portions 750 of the plurality of light-receiving elements 75-1 to M, respectively. Each of the plurality of light-receiving elements 75-1 to M converts the received optical signal into an electric signal (hereinafter, also referred to as a signal). Each of the plurality of light-receiving elements 75-1 to M outputs the converted signal to the decoder 76. Each of the plurality of light-receiving elements 75-1 to M has the same configuration as the light-receiving element 15 of the first example embodiment.

The decoder 76 acquires a signal output from each of the plurality of light-receiving elements 75-1 to M. The decoder 76 amplifies a signal from each of the plurality of light-receiving elements 75-1 to M. The decoder 76 decodes the amplified signal and analyzes a signal from the communication target. For example, the decoder 76 collectively analyzes the signals of the plurality of light-receiving elements 75-1 to M. In a case where the signals of the plurality of light-receiving elements 75-1 to M are collectively analyzed, it is possible to achieve the single-channel light-receiving device 70 that communicates with a single communication target. For example, the decoder 76 individually analyzes a signal for each of the plurality of light-receiving elements 75-1 to M. In a case where signals are individually analyzed for each of the plurality of light-receiving elements 75-1 to M, it is possible to achieve the multi-channel light-receiving device 70 that simultaneously communicates with a plurality of communication targets. The signal decoded by the decoder 76 is used for any purpose. The use of the signal decoded by the decoder 76 is not particularly limited.

[Decoder]

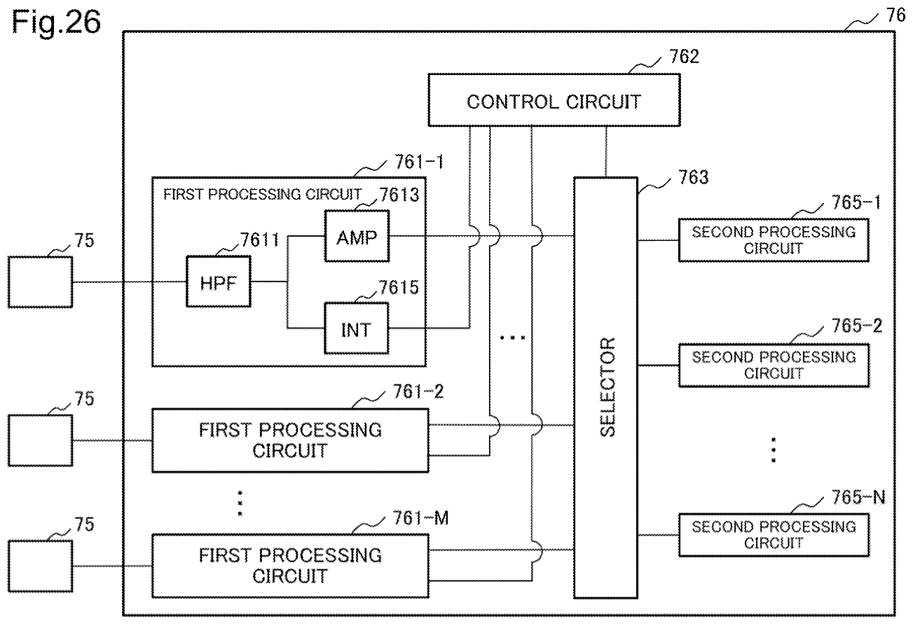

Next, an example of a detailed configuration of the decoder 76 included in the light-receiving device 70 will be described with reference to the drawings. FIG. 26 is a block diagram illustrating an example of a configuration of the decoder 76. The decoder 76 includes a plurality of first processing circuits 761-1 to M, a control circuit 762, a selector 763, and a plurality of second processing circuits 765-1 to N (N is a natural number). In FIG. 26, only the internal configuration of the first processing circuit 761-1 among the plurality of first processing circuits 761-1 to M is illustrated, but the internal configuration of each of the plurality of first processing circuits 761-2 to M is also similar to that of the first processing circuit 761-1.

The first processing circuit 761 is associated with any one of the plurality of light-receiving elements 75-1 to M. The first processing circuit 761 includes a high-pass filter 7611, an amplifier 7613, and an integrator 7615. In FIG. 26, the high-pass filter 7611 is referred to as a high path filter (HPF), the amplifier 7613 is referred to as an amplifier (AMP), and the integrator 7615 is referred to as an integrator (INT). The high-pass filter 7611 of each of the plurality of first processing circuits 761-1 to M acquires a signal from any one of the light-receiving elements 75-1 to M associated with the plurality of respective first processing circuits 761-1 to M. Each of the plurality of light-receiving elements 75-1 to M and each of the plurality of first processing circuits 761-1 to M related thereto constitute a unit unit. The signal having passed through the high-pass filter 7611 of each of the plurality of first processing circuits 761-1 to M is input in parallel to the amplifier 7613 and the integrator 7615.

The high-pass filter 7611 acquires a signal from the light-receiving element 75. The high-pass filter 7611 selectively passes a signal of a high frequency component related to the wavelength band of the spatial optical signal among the acquired signals. The high-pass filter 7611 cuts off a signal derived from ambient light such as sunlight. Instead of the high-pass filter 7611, a band pass filter that selectively passes a signal in a wavelength band of a spatial optical signal may be configured. When light-receiving element 75 is saturated with intense sunlight, an optical signal cannot be read. Therefore, a color filter that selectively passes the light in the wavelength band of the spatial optical signal may be installed before the light-receiving surface of the light-receiving element 75. The signal that has passed through the high-pass filter 7611 is supplied to the amplifier 7613 and the integrator 7615.

The amplifier 7613 acquires the signal output from the high-pass filter 7611. The amplifier 7613 amplifies the acquired signal. The amplifier 7613 outputs the amplified signal to a selector 763. Among the signals output to the selector 763, the signal to be received is allocated to any one of the plurality of second processing circuits 765-1 to N under the control of the control circuit 762. The signal to be received is a spatial optical signal from a communication device (not illustrated) to be communicated. A signal from the light-receiving element 75 that is not used for receiving the spatial optical signal is not output to the second processing circuit 765.

The integrator 7615 acquires the signal output from the high-pass filter 7611. The integrator 7615 integrates the acquired signal. The integrator 7615 outputs the integrated signal to the control circuit 762.

The integrator 7615 is disposed to measure the intensity of the spatial optical signal received by the light-receiving element 75. In the present example embodiment, the spatial optical signal in a state in which the beam diameter is spread is received by the face on the incident face of the condenser lens 71, thereby increasing the speed of searching for the communication target. Since the intensity of the spatial optical signal received in a state where the beam diameter is not narrowed is weaker than that of the signal in a state where the beam diameter is narrowed, it is difficult to measure the voltage of the signal amplified only by the amplifier 7613. By using the integrator 7615, for example, the voltage of the signal can be increased to a level at which the voltage can be measured by integrating the signal for several milliseconds (msec) to several tens of milliseconds.

The control circuit 762 acquires a signal output from the integrator 7615 included in each of the plurality of first processing circuits 761-1 to M. In other words, the control circuit 762 acquires a signal derived from an optical signal received by each of the plurality of light-receiving elements 75-1 to M. For example, the control circuit 762 compares the read values of the signals from the plurality of light-receiving elements 75 adjacent to each other, and selects the light-receiving element 75 having the maximum signal intensity. The control circuit 762 controls the selector 763 in such a way as to allocate the signal derived from the selected light-receiving element 75 to any one of the plurality of second processing circuits 765-1 to N.

The control circuit 762 selecting the light-receiving element 75 corresponds to estimating the incoming direction of the spatial optical signal. That is, the control circuit 762 selecting the light-receiving element 75 corresponds to identifying the communication device of the light transmission source of the spatial optical signal. Allocating the signal from the light-receiving element 75 selected by the control circuit 762 to any one of the plurality of second processing circuits corresponds to associating the identified communication target with the light-receiving element 75 that receives the spatial optical signal from the communication target. That is, the control circuit 762 identifies the communication device of the light transmission source of the optical signal (spatial optical signal) based on the optical signal received by the plurality of light-receiving elements 750-1 to M. In a case where the position of the communication target is identified in advance, the signals output from the light-receiving elements 75-1 to M may be decoded as they are without performing the process of estimating the incoming direction of the spatial optical signal.

The signal amplified by the amplifier 7613 included in each of the plurality of first processing circuits 761-1 to M is input to the selector 763. The selector 763 outputs a signal to be received among the input signals to any of the plurality of second processing circuits 765-1 to N according to the control of the control circuit 762. A signal that is not to be received is not output from the selector 763.

A signal from any one of the plurality of light-receiving elements 75-1 to N allocated by the control circuit 762 is input to any of the plurality of second processing circuits 765-1 to N. Each of the plurality of second processing circuits 765-1 to N decodes the input signal. Each of the plurality of second processing circuits 765-1 to N may be configured to perform some signal processing on the decoded signal, or may be configured to output the signal to an external signal processing device or the like (not illustrated).

When the selector 763 selects a signal derived from the light-receiving element 75 selected by the control circuit 762, one second processing circuit 765 is allocated to one communication target. That is, the control circuit 762 allocates the signals derived from the spatial optical signals from the plurality of communication targets received by the plurality of light-receiving elements 75-1 to M to any of the plurality of second processing circuits 765-1 to N. As a result, the light-receiving device 70 can simultaneously read signals derived from spatial optical signals from a plurality of communication targets on individual channels. In the case of the sixth example embodiment, in order to simultaneously communicate with a plurality of communication targets, spatial optical signals from the plurality of communication targets are read in time division manner in one channel. On the other hand, in the method of the present example embodiment, since spatial optical signals from a plurality of communication targets are simultaneously read in a plurality of channels, the transmission speed is improved. The method of the present example embodiment may also be configured to receive signals in a time division manner depending on the situation.

For example, the scan of the communication target may be performed as a primary scan, and the incoming direction of the spatial optical signal may be identified with coarse accuracy. Then, secondary scanning with fine accuracy may be performed in the identified direction to identify a more accurate position of the communication target. When communication with the communication target is possible, an accurate position of the communication target can be determined by exchanging signals with the communication target. When the position of the communication target is identified in advance, the process of identifying the position of the communication target may be omitted.

As described above, the light-receiving device of the present example embodiment includes the condenser lens, the beam control element, the plurality of light-receiving elements, and the plurality of decoders. The condenser lens receives a spatial optical signal. The beam control element includes a plurality of beam control regions associated with the plurality of respective predetermined regions. The beam control element emits the optical signal incident on each of the plurality of beam control regions toward a predetermined region associated with the beam control region. Each of the plurality of light-receiving elements is disposed with the light-receiving portion facing any of the plurality of predetermined regions. Each of the plurality of light-receiving elements receives an optical signal. Each of the plurality of decoders is connected to any one of the plurality of light-receiving elements. The decoder decodes a signal based on the optical signal received by the light-receiving element.

According to the light-receiving device of the present example embodiment, a signal based on a spatial optical signal coming from any direction can be decoded for each incoming direction. For example, according to the light-receiving device of the present example embodiment, it is possible to achieve a multi-channel receiving device in conformance to an incoming direction of a spatial optical signal.

### Eighth Example Embodiment

Next, a communication device according to the eighth example embodiment will be described with reference to the drawings. The communication device of the present example embodiment includes the light-receiving device of the sixth example embodiment and a light transmitting unit that transmits a spatial optical signal according to a received spatial optical signal. Hereinafter, an example of a communication device including a light transmitting unit including a phase modulation-type spatial light modulator will be described. The communication device of the present example embodiment may include a light transmitting unit including a light transmission function that is not a phase modulation-type spatial light modulator. The communication device of the present example embodiment may have a wireless communication function. The communication device of the present example embodiment may have a configuration in which the light-receiving device of the seventh example embodiment and the light transmitting unit are combined. As in the fourth example embodiment, a reflection type beam control element may be applied to the communication device of the present example embodiment. The communication device of the present example embodiment may be combined with the light pipe of the second example embodiment and the fiber bundle of the fifth example embodiment.

(Configuration)

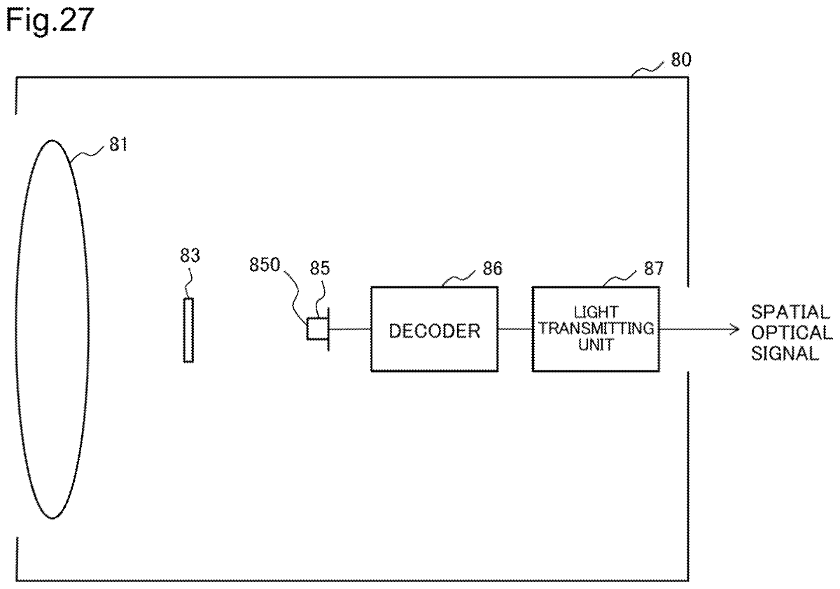

FIG. 27 is a conceptual diagram illustrating an example of a configuration of a communication device 80 of the present example embodiment. The communication device 80 includes a condenser lens 81, a beam control element 83, a light-receiving element 85, a decoder 86, and a light transmitting unit 87. FIG. 27 is a diagram of the internal configuration of the communication device 80 when viewed from the lateral direction. The positions of the decoder 86 and the light transmitting unit 87 are not particularly limited. The decoder 86 and the light transmitting unit 87 may be disposed inside the communication device 80 or may be disposed outside the communication device 80.

The condenser lens 81 is an optical element that condenses a spatial optical signal coming from the outside. The optical signal condensed by the condenser lens 81 is condensed toward the incident face of the beam control element 83. The condenser lens 81 has the same configuration as the condenser lens 11 of the first example embodiment. The condenser lens 81 may be configured to condense light in accordance with the shape of the beam control element 83.

Light beam control element 83 is disposed behind the condenser lens 81. The beam control element 83 is disposed in such a way that the incident face faces an emission face of the condenser lens 81. For example, as in the third example embodiment, the beam control element 83 is set in a shape conforming to the incoming direction of the spatial light. The beam control element 83 may be configured to cope with spatial light coming from any direction as in the first example embodiment. The beam control element 83 may be a reflection type as in the fourth example embodiment. The beam control element 83 may include a plurality of beam control regions as in the seventh example embodiment. Since the beam control element 83 is similar to any of the first to seventh example embodiments, a detailed description thereof will be omitted.

The light-receiving element 85 is disposed behind the beam control element 83. The light-receiving element 85 includes a light-receiving portion 850 that receives the optical signal emitted from the beam control element 83. The light-receiving element 85 is disposed in such a way that light-receiving portion 850 faces the emission face of the beam control element 83. The optical signal emitted from the beam control element 83 is received by the light-receiving portion 850 of the light-receiving element 85. The light-receiving element 85 converts the received optical signal into an electric signal (hereinafter, also referred to as a signal). The light-receiving element 85 outputs the converted signal to the decoder 86. The light-receiving element 85 has the same configuration as the light-receiving element 15 of the first example embodiment. A plurality of light-receiving elements 85 may be disposed as in the seventh example embodiment.

The decoder 86 acquires a signal output from the light-receiving element 85. The decoder 86 amplifies the signal from the light-receiving element 85. The decoder 86 decodes the amplified signal and analyzes a signal from the communication target. The decoder 86 outputs a control signal for transmitting an optical signal according to the signal analysis result to the light transmitting unit 87.

The light transmitting unit 87 acquires a control signal from the decoder 86. The light transmitting unit 87 projects a spatial optical signal related to the control signal. The spatial optical signal projected from the light transmitting unit 87 is received by a communication target (not illustrated). For example, the light transmitting unit 87 includes a phase modulation-type spatial light modulator. The light transmitting unit 87 may include a light transmission function that is not a phase modulation-type spatial light modulator.

[Light Transmitting Unit]

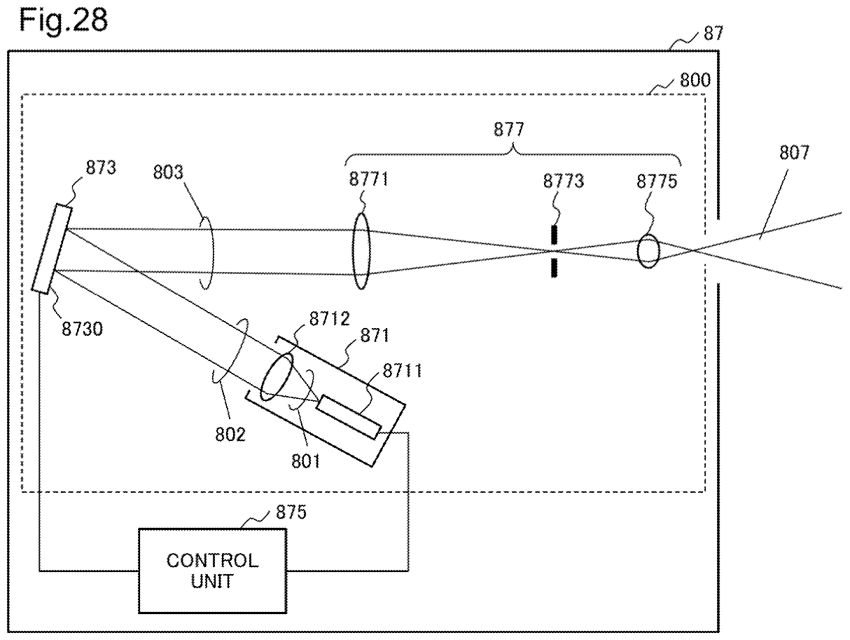

Next, an example of a detailed configuration of the light transmitting unit 87 will be described with reference to the drawings. FIG. 28 is a conceptual diagram illustrating an example of a detailed configuration of the light transmitting unit 87. The light transmitting unit 87 includes an irradiation unit 871, a spatial light modulator 873, a control unit 875, and a projection optical system 877. The irradiation unit 871, the spatial light modulator 873, and the projection optical system 877 constitute a light projecting unit 800. The light projecting unit 800 projects a spatial optical signal under the control of the control unit 875. FIG. 28 is conceptual, and does not accurately represent the positional relationship between the components, the traveling direction of light, and the like.

The irradiation unit 871 emits coherent light 802 having a specific wavelength. As illustrated in FIG. 28, the irradiation unit 871 includes a light source 8711 and a collimator lens 8712. As illustrated in FIG. 28, the light 801 emitted from the irradiation unit 871 passes through the collimator lens 8712 to become coherent light 802, and is incident on the modulation part 8730 of the spatial light modulator 873. For example, the light source 8711 includes a laser light source. For example, the light source 8711 is configured to emit light 801 in the infrared region. The light source 8711 may be configured to emit light 801 other than the infrared region, such as the visible region and the ultraviolet region. The irradiation unit 871 is connected to a power supply (also referred to as a light source driving power supply) driven according to the control of the control unit 875. The light 801 is emitted from the light source 8711 in response to the driving of the light source driving power supply.

Under the control of the control unit 875, the spatial light modulator 873 sets a pattern (phase distribution related to the spatial optical signal) for projecting the spatial optical signal in its own modulation part 8730. In the present example embodiment, the modulation part 8730 of the spatial light modulator 873 is irradiated with the light 802 in a state where a predetermined pattern is displayed on the modulation part 8730. The spatial light modulator 873 emits reflected light (modulated light 803) of the light 802 incident on the modulation part 8730 toward the projection optical system 877.

As illustrated in FIG. 28, in the present example embodiment, the incident angle of the light 802 is made non-perpendicular to the incident face of the modulation part 8730 of the spatial light modulator 873. That is, in the present example embodiment, the emission axis of the light 802 from the irradiation unit 871 is inclined with respect to the modulation part 8730 of the spatial light modulator 873, and the light 802 is made incident on the modulation part 8730 of the spatial light modulator 873 without using the beam splitter. In the configuration of FIG. 28, since the light 802 is not attenuated by passing through the beam splitter, utilization efficiency of the light 802 can be improved.

The spatial light modulator 873 can be achieved by a phase modulation-type spatial light modulator that receives the incidence of the coherent light 802 having the same phase and modulates the phase of the incident light 802. Since the light emitted from the projection optical system 877 using the phase modulation-type spatial light modulator 873 is focus-free, it is not necessary to change the focus for each projection distance even when the light is projected with a plurality of projection distances.

A phase distribution related to the spatial optical signal is displayed on the modulation part 8730 of the phase modulation-type spatial light modulator 873 according to the drive of the control unit 875. The modulated light 803 obtained by reflection of the light by the modulation part 8730, of the spatial light modulator 873, on which the phase distribution is displayed is an image in which a kind of diffraction grating forms an aggregate, and the image is formed in such a way that light diffracted by the diffraction grating gathers.

The spatial light modulator 873 is achieved by, for example, a spatial light modulator including ferroelectric liquid crystal, homogeneous liquid crystal, vertical alignment liquid crystal, or the like. Specifically, the spatial light modulator 873 can be achieved by liquid crystal on silicon (LCOS). For example, the spatial light modulator 873 may be achieved by a micro electro mechanical system (MEMS).

In the phase modulation-type spatial light modulator 873, the energy can be concentrated on the portion of the image by operating to sequentially switch the portion on which the projection light is projected. Therefore, when the phase modulation-type spatial light modulator 873 is used, it is possible to display the display information brighter than those of other types when the outputs of the light sources are the same.

The control unit 875 displays, on the modulation part 8730 of the spatial light modulator 873, a pattern related to the spatial optical signal according to the control signal from the decoder 86. The control unit 875 drives the spatial light modulator 873 in such a way that a parameter that determines a difference between a phase of the light 801 with which the modulation part 8730 of the spatial light modulator 873 is irradiated and a phase of the modulated light 803 obtained by reflection of the light by the modulation part 8730 changes.

The parameter determining the difference between the phase of the light 802 with which the modulation part 8730 of the phase modulation-type spatial light modulator 873 is irradiated and the phase of the modulated light 803 obtained by reflection of the light by the modulation part 8730 is, for example, a parameter regarding optical characteristics such as a refractive index and an optical path length. For example, the control unit 875 changes the refractive index of the modulation part 8730 by changing the voltage applied to the modulation part 8730 of the spatial light modulator 873. When the refractive index of modulation part 8730 is changed, light 802 with which the modulation part 8730 is irradiated is appropriately diffracted based on the refractive index of each portion of modulation part 8730. That is, the phase distribution of the light 802 with which the phase modulation-type spatial light modulator 873 is irradiated is modulated according to the optical characteristics of the modulation part 8730. The method of driving the spatial light modulator 873 by the control unit 875 is not limited to the method described herein.

The projection optical system 877 projects the modulated light 803 modulated by the spatial light modulator 873 as projection light 807 (also referred to as a spatial optical signal). As illustrated in FIG. 28, the projection optical system 877 includes a Fourier transform lens 8771, an aperture 8773, and a projection lens 8775. The modulated light 803 modulated by the spatial light modulator 873 is emitted as projection light 807 by the projection optical system 877. Any of the components of the projection optical system 877 may be omitted as long as an image can be formed in the projection range. For example, in a case where the image related to the phase distribution set in the modulation part 8730 of the spatial light modulator 873 is enlarged using the virtual lens, the Fourier transform lens 8771 can be omitted. A configuration other than the Fourier transform lens 8771, the aperture 8773, and the projection lens 8775 may be added to the projection optical system 877 as necessary.

The Fourier transform lens 8771 is an optical lens for forming an image formed by projecting the modulated light 803 reflected by the modulating section 8730 of the spatial light modulator 873 to infinity at a nearby focal point. In FIG. 28, a focal point is formed at the position of the aperture 8773.

The aperture 8773 shields high-order light included in the light focused by the Fourier transform lens 8771, and identifies a range in which the projection light 807 is displayed. The opening of the aperture 8773 is opened smaller than the outermost periphery of the display area at the position of the aperture 8773, and is installed in such a way as to block the peripheral region of the display information at the position of the aperture 8773. For example, the opening of the aperture 8773 is formed in a rectangular shape or a circular shape. The aperture 8773 is preferably provided at the focal position of the Fourier transform lens 8771, but may be shifted from the focal position as long as a function of erasing high-order light can be exhibited.

The projection lens 8775 is an optical lens that enlarges and projects the light focused by the Fourier transform lens 8771. The projection lens 8775 projects the projection light 807 in such a way that the display information related to the phase distribution displayed on the modulation part 8730 of the spatial light modulator 873 is projected within the projection range.

When a line drawing such as a simple symbol is projected, the projection light 807 projected from the projection optical system 877 is not uniformly projected toward the entire projection range, but is intensively projected onto a portion such as a character, a symbol, or a frame constituting an image. Therefore, according to the communication device 80 of the present example embodiment, since the emission amount of the light 801 can be substantially reduced, the overall light output can be suppressed. That is, since the communication device 80 can be achieved by the small and low-power irradiation unit 871, the light source driving power supply (not illustrated) for driving the irradiation unit 871 can be reduced in output, and the overall power consumption can be reduced.

When the irradiation unit 871 is configured to emit light of a plurality of wavelengths, the wavelength of the light emitted from the irradiation unit 871 can be changed. When the wavelength of the light emitted from the irradiation unit 871 is changed, the color of the spatial optical signal can be multicolored. When the irradiation unit 871 that simultaneously emits light of different wavelengths is used, communication using spatial optical signals of a plurality of colors is possible.

### Application Example

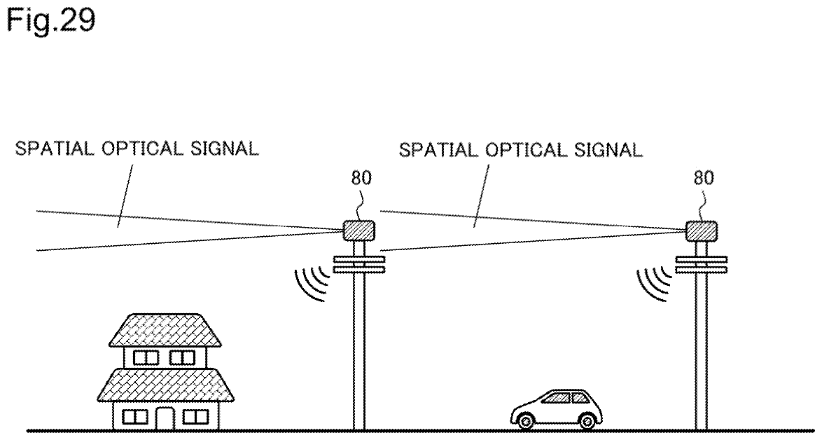

FIG. 29 is a conceptual diagram for describing an application example of the communication device 80 of the present example embodiment. In the present application example, the communication device 80 is disposed on an upper portion of a utility pole. In the present application example, the communication device 80 has a function of performing wireless communication.

Since there are few obstacles between the poles, the upper portion of the pole is suitable for installing the communication device 80. When the communication devices 80 are installed at the same height on the upper portion of the utility pole, the incoming direction of the spatial optical signal is limited to the horizontal direction, so that the shape of the beam control element can be elongated in the horizontal direction as in the third to seventh example embodiments. The two communication devices 80 that exchange communication are disposed in such a way that one communication device 80 receives the spatial optical signal transmitted from the other communication device 80. In a case where there are only two communication devices 80, the communication devices may be disposed in such a way as to transmit and receive spatial optical signals to and from each other. In a case where the communication network of the spatial optical signal is configured by the plurality of communication devices 80, the communication device 80 positioned in the middle may be disposed to relay the spatial optical signal transmitted from another communication device 80 to another communication device 80.

According to the present application example, communication using a spatial optical signal can be performed between a plurality of communication devices 80 installed on different utility poles. For example, according to the present application example, it is also possible to perform communication by wireless communication between a wireless device installed in an automobile, a house, or the like and the communication device 80 according to communication between the communication devices 80 installed on different utility poles.

As described above, the communication device of the present example embodiment includes a condenser lens, a beam control element, a light-receiving element, a decoder, and a light transmitting unit. The condenser lens receives a spatial optical signal. The beam control element emits an optical signal derived from the spatial optical signal condensed by the condenser lens toward a predetermined region. The light-receiving element is disposed with the light-receiving portion facing a predetermined region. The light-receiving element receives an optical signal. The decoder decodes a signal based on the optical signal received by the light-receiving element. The light transmitting unit transmits a spatial optical signal related to the signal decoded by the decoder.

According to the communication device of the present example embodiment, communication using a spatial optical signal is possible. For example, when a plurality of communication devices is disposed in such a way that spatial optical signals can be transmitted and received, a communication network using the spatial optical signals can be constructed.

In an aspect of the present example embodiment, the light transmitting unit includes a light source, a spatial light modulator, a control unit, and a projection optical system. The light source emits parallel light. The spatial light modulator includes a modulation part that modulates the phase of the parallel light emitted from the light source. The control unit sets a phase image related to the spatial optical signal in the modulation part, and controls the light source in such a way that parallel light is emitted toward the modulation part in which the phase image is set. The projection optical system projects the light modulated by the modulation part.

Since the communication device of the present aspect includes the phase modulation-type spatial light modulator, it is possible to transmit a spatial optical signal having a similar brightness with low power consumption as compared with a communication device including a general light transmission mechanism.

### Ninth Example Embodiment

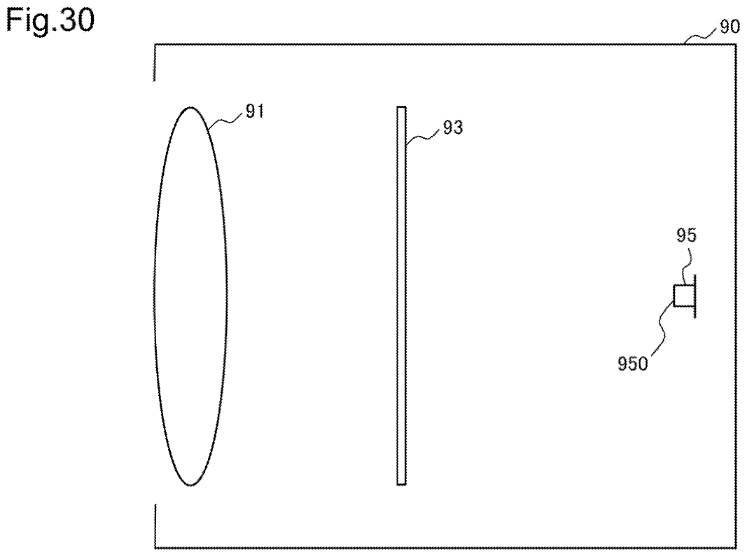

Next, a light-receiving device according to the ninth example embodiment will be described with reference to the drawings. The light-receiving device of the present example embodiment has a simplified configuration of the light-receiving devices of the first to eighth example embodiments. FIG. 30 is a conceptual diagram illustrating an example of a configuration of a light-receiving device 90 of the present example embodiment. The light-receiving device 90 includes a condenser lens 91, a beam control element 93, and a light-receiving element 95.

The condenser lens 91 receives a spatial optical signal. The beam control element 93 emits an optical signal derived from the spatial optical signal condensed by the condenser lens 91 toward a predetermined region. The light-receiving element 95 is disposed with the light-receiving portion facing a predetermined region, and receives an optical signal.

According to the light-receiving device of the present example embodiment, by guiding the optical signal condensed by the condenser lens to the predetermined region by the beam control element, the spatial optical signal coming from any direction can be efficiently received.

(Hardware)

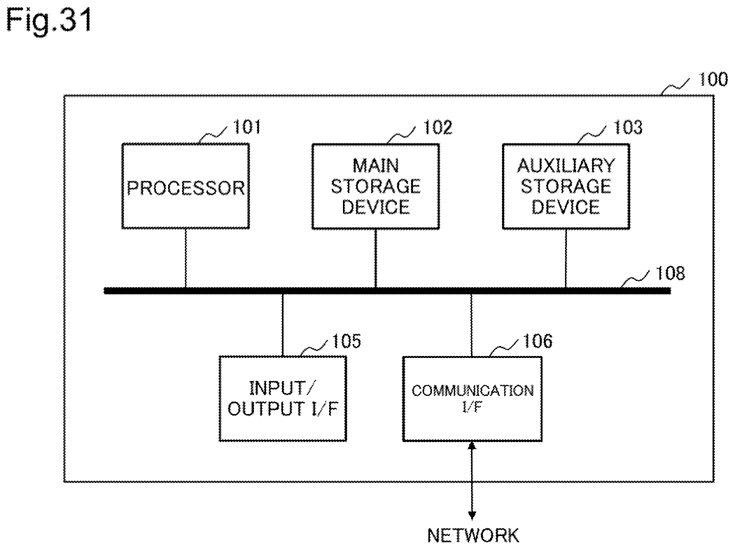

A hardware configuration for executing control and processing according to each example embodiment of the present disclosure will be described using an information processing device 100 of FIG. 31 as an example. The information processing device 100 in FIG. 31 is a configuration example for executing control and processing of each example embodiment, and does not limit the scope of the present disclosure.

As illustrated in FIG. 31, the information processing device 100 includes a processor 101, a main storage device 102, an auxiliary storage device 103, an input/output interface 105, and a communication interface 106. In FIG. 31, the interface is abbreviated as an interface (I/F). The processor 101, the main storage device 102, the auxiliary storage device 103, the input/output interface 105, and the communication interface 106 are data-communicably connected to each other via a bus 108. The processor 101, the main storage device 102, the auxiliary storage device 103, and the input/output interface 105 are connected to a network such as the Internet or an intranet via the communication interface 106.

The processor 101 develops the program stored in the auxiliary storage device 103 or the like in the main storage device 102 and executes the developed program. In each example embodiment, a software program installed in the information processing device 100 may be used. The processor 101 executes control and processing according to each example embodiment.

The main storage device 102 has an area in which a program is developed. The main storage device 102 may be a volatile memory such as a dynamic random access memory (DRAM). A nonvolatile memory such as a magnetoresistive random access memory (MRAM) may be configured and added as the main storage device 102.

The auxiliary storage device 103 stores various pieces of data. The auxiliary storage device 103 includes a local disk such as a hard disk or a flash memory. Various pieces of data may be stored in the main storage device 102, and the auxiliary storage device 103 may be omitted.

The input/output interface 105 is an interface that connects the information processing device 100 with a peripheral device. The communication interface 106 is an interface that connects to an external system or a device through a network such as the Internet or an intranet in accordance with a standard or a specification. The input/output interface 105 and the communication interface 106 may be shared as an interface connected to an external device.

An input device such as a keyboard, a mouse, or a touch panel may be connected to the information processing device 100 as necessary. These input devices are used to input of information and settings. When the touch panel is used as the input device, the display screen of the display device may also serve as the interface of the input device. Data communication between the processor 101 and the input device may be mediated by the input/output interface 105.

The information processing device 100 may be provided with a display device that displays information. In a case where a display device is provided, the information processing device 100 preferably includes a display control device (not illustrated) that controls display of the display device. The display device may be connected to the information processing device 100 via the input/output interface 105.

The information processing device 100 may be provided with a drive device. The drive device mediates reading of data and a program from the recording medium, writing of a processing result of the information processing device 100 to the recording medium, and the like between the processor 101 and the recording medium (program recording medium). The drive device may be connected to the information processing device 100 via the input/output interface 105.

The above is an example of a hardware configuration for executing control and processing according to each example embodiment. The hardware configuration of FIG. 31 is an example of a hardware configuration for executing control and processing according to each example embodiment, and does not limit the scope of the present invention. A program for causing a computer to execute control and processing according to each example embodiment is also included in the scope of the present invention. A program recording medium in which the program according to each example embodiment is recorded is also included in the scope of the present invention. The recording medium can be achieved by, for example, an optical recording medium such as a compact disc (CD) or a digital versatile disc (DVD). The recording medium may be achieved by a semiconductor recording medium such as a Universal Serial Bus (USB) memory or a secure digital (SD) card, a magnetic recording medium such as a flexible disk, or another recording medium. In a case where the program executed by the processor is recorded in the recording medium, the recording medium is a program recording medium.

The components that execute the control and processing of each example embodiment can be combined in any manner. Components that execute control and processing of each example embodiment may be achieved by software or may be achieved by a circuit.

While the present invention is described with reference to example embodiments thereof, the present invention is not limited to these example embodiments. Various modifications that can be understood by those of ordinary skill can be made to the configuration and details of the present invention within the scope of the present invention.

Some or all of the above example embodiments may be described as the following Supplementary Notes, but are not limited to the following.

(Supplementary Note 1)

A light-receiving device including
a condenser lens that condenses a spatial optical signal,
a beam control element that emits an optical signal derived from the spatial optical signal condensed by the condenser lens toward a predetermined region, and
a light-receiving element that is disposed with a light-receiving portion facing the predetermined region and receives the optical signal.

(Supplementary Note 2)

The light-receiving device according to Supplementary Note 1, wherein
the beam control element
is a near-field diffractive optical element that diffracts the optical signal condensed by the condenser lens toward the predetermined region.

(Supplementary Note 3)

The light-receiving device according to Supplementary Note 1, wherein
the beam control element
is a reflection type diffractive optical element that diffracts and reflects the optical signal condensed by the condenser lens toward the predetermined region.

(Supplementary Note 4)

The light-receiving device according to any one of Supplementary Notes 1 to 3, further including a light pipe that guides the optical signal emitted from the beam control element, to the light-receiving portion disposed at the predetermined region.

(Supplementary Note 5)

The light-receiving device according to Supplementary Note 4, wherein
the light pipe
has a hollow structure, and includes a directional light guide body that directionally guides the optical signal toward the light-receiving portion disposed at the predetermined region, the directional light guide being located, on an inner face of the light pipe, at least in a vicinity of an incident face.

(Supplementary Note 6)

The light-receiving device according to any one of Supplementary Notes 1 to 3, further including a fiber bundle including a bundle of a plurality of optical fibers that guides the optical signal emitted from the beam control element, to the light-receiving portion disposed at the predetermined region.

(Supplementary Note 7)

The light-receiving device according to Supplementary Note 6, wherein each of the plurality of optical fibers included in the fiber bundle is disposed in such a way that a cross section of an incident end of each of the plurality of optical fibers is substantially perpendicular to an optical axis of the optical signal emitted from the beam control element.

(Supplementary Note 8)

The light-receiving device according to any one of Supplementary Notes 1 to 7, wherein
the beam control element
has a shape conforming to an incoming direction of the spatial optical signal.

(Supplementary Note 9)

The light-receiving device according to any one of Supplementary Notes 1 to 8, further including a decoder that decodes a signal based on the optical signal received by the light-receiving element.

(Supplementary Note 10)

The light-receiving device according to Supplementary Note 9, comprising
a plurality of the light-receiving elements, and
a plurality of the decoders, wherein
each of the plurality of the light-receiving elements
is disposed with the light-receiving portion facing any of a plurality of the predetermined regions, wherein
each of the plurality of the decoders
is connected to any of the plurality of the light-receiving elements, and wherein
the beam control element
includes a plurality of beam control regions associated with the plurality of respective predetermined regions, and emits the optical signal incident on each of the plurality of beam control regions toward a predetermined region associated with each of the beam control regions.

(Supplementary Note 11)

A communication device including
the light-receiving device according to Supplementary Note 9 or 10, and
a light transmitting unit that transmits a spatial optical signal related to a signal decoded by the decoder.

(Supplementary Note 12)

The communication device according to Supplementary Note 11, wherein
the light transmitting unit includes
a light source that emits parallel light,
a spatial light modulator including a modulation part that modulates a phase of the parallel light emitted from the light source,
a control unit that sets a phase image related to the spatial optical signal in the modulation part and controls the light source in such a way that the parallel light is emitted toward the modulation part in which the phase image is set, and
a projection optical system that projects light modulated by the modulation part.

This application claims priority based on Japanese Patent Application No. 2021 000310 filed on Jan. 5, 2021 and Japanese Patent Application No. 2021-106392 filed on Jun. 28, 2021, the entire disclosure of which is incorporated herein by reference.

### REFERENCE SIGNS LIST

10, 20, 30, 40, 50, 60, 90 light-receiving device
11, 21, 31, 41, 51, 61, 71, 81, 91 condenser lens
13, 23, 33, 43, 53, 63, 73, 83, 93 beam control element
15, 25, 35, 45, 55, 65, 75, 85, 95 light-receiving element
24 light pipe
54 fiber bundle
66, 76, 86 decoder
80 communication device
87 light transmitting unit
661 amplifier circuit
665 decode circuit
761 first processing circuit
765 second processing circuit
762 control circuit
763 selector
800 light projecting unit
871 irradiation unit
873 spatial light modulator
877 projection optical system
7611 high-pass filter
7613 amplifier
7615 integrator
8711 light source
8712 collimator lens
8771 Fourier transform lens
8773 aperture
8775 projection lens

What is claimed is:

1. A light-receiving device comprising:
a condenser lens that condenses a spatial optical signal;
a beam control element that emits an optical signal derived from the spatial optical signal condensed by the condenser lens toward a predetermined region; and
a light-receiving element that is disposed with a light-receiving portion facing the predetermined region and receives the optical signal.

2. The light-receiving device according to claim 1, wherein
the beam control element is
a near-field diffractive optical element that diffracts the optical signal condensed by the condenser lens toward the predetermined region.

3. The light-receiving device according to claim 1, wherein
the beam control element is
a reflection type diffractive optical element that diffracts and reflects the optical signal condensed by the condenser lens toward the predetermined region.

4. The light-receiving device according to claim 1, further comprising a light pipe that guides the optical signal emitted from the beam control element, to the light-receiving portion disposed at the predetermined region.

5. The light-receiving device according to claim 4, wherein
the light pipe has a hollow structure, and includes a directional light guide body that directionally guides the optical signal toward the light-receiving portion disposed at the predetermined region, the directional light guide being located, on an inner face of the light pipe, at least in a vicinity of an incident face.

6. The light-receiving device according to claim 1, further comprising a fiber bundle including a bundle of a plurality of optical fibers that guides the optical signal emitted from the beam control element, to the light-receiving portion disposed at the predetermined region.

7. The light-receiving device according to claim 6, wherein
each of the plurality of optical fibers included in the fiber bundle is disposed in such a way that a cross section of an incident end of each of the plurality of optical fibers is substantially perpendicular to an optical axis of the optical signal emitted from the beam control element.

8. The light-receiving device according to claim 1, wherein
the beam control element
has a shape conforming to an incoming direction of the spatial optical signal.

9. The light-receiving device according to claim 1, further comprising a decoder that decodes a signal based on the optical signal received by the light-receiving element.

10. The light-receiving device according to claim 9, comprising
a plurality of the light-receiving elements, and
a plurality of the decoders, wherein
each of the plurality of the light-receiving elements
is disposed with the light-receiving portion facing any of a plurality of the predetermined regions, wherein
each of the plurality of the decoders
is connected to any of the plurality of the light-receiving elements, and wherein
the beam control element
includes a plurality of beam control regions associated with the plurality of respective predetermined regions, and emits the optical signal incident on each of the plurality of beam control regions toward a predetermined region associated with each of the beam control regions.

11. A communication device comprising:
the light-receiving device according to claim 9; and
a light transmitter that transmits a spatial optical signal related to a signal decoded by the decoder.

12. The communication device according to claim 11, wherein
the light transmitter includes
a light source that emits parallel light,
a spatial light modulator including a modulation part that modulates a phase of the parallel light emitted from the light source,
a controller that sets a phase image related to the spatial optical signal in the modulation part and controls the light source in such a way that the parallel light is emitted toward the modulation part in which the phase image is set, and
a projection optical system that projects light modulated by the modulation part.
